(19) United States
(12) Patent Application Publication
(10) Pub. No.: US 2026/0362858 A1
(43) Pub. Date: Nov. 12, 2026

(54) PRETREATMENT METHOD FOR CERAMIC PLATE, CERAMIC PLATE, LIGHT-EMITTING DEVICE, AND MANUFACTURING METHOD FOR CERAMIC SUBSTRATE AND LIGHT-EMITTING DEVICE

(71) Applicant: NICHIA CORPORATION, Anan-shi (JP)

(72) Inventor: Takeshi SADAMOCHI, Tokushima-shi (JP)

(73) Assignee: NICHIA CORPORATION, Anan-shi (JP)

(21) Appl. No.: 19/655,699

(22) Filed: Apr. 23, 2026

(30) Foreign Application Priority Data
Apr. 30, 2025 (JP) 2025-075739

(51) Int. Cl. H10H 20/85; H10H 20/01

(52) U.S. Cl. CPC H10H 20/8508; H10H 20/036; H10H 20/8504

(57) ABSTRACT

A pretreatment method for a ceramic plate used for laser beam machining includes changing a chroma C* of a ceramic plate material by irradiating the ceramic plate material with ultraviolet light having a wavelength of 300 nm or less.

### CROSS-REFERENCE TO RELATED APPLICATIONS

The present application claims priority under 35 U.S.C. § 119 to Japanese Patent Application No. 2025-075739, filed Apr. 30, 2025, the content of which is hereby incorporated by reference in its entirety.

### BACKGROUND

### 1. Technical Field

The present disclosure relates to a pretreatment method for a ceramic plate, a light-emitting device, and a manufacturing method for a ceramic substrate and a light-emitting device.

### 2. Description of Related Art

In recent years, substrates have been proposed in which through-holes (also referred to as holes, vias, or the like) are formed in an insulating substrate and a conductive material such as copper or silver is disposed in the through-holes to electrically connect both surfaces of the substrate, thereby enabling miniaturization, enhanced functionality, and integration of electronic equipment or components.

When through-holes are formed by irradiating an insulating substrate using a material that reflects laser light with a laser beam, it is difficult to form the through-holes because the laser beam is reflected on the surface of the insulating substrate. A manufacturing method for a ceramic electronic component is known in which a conductor layer is formed by applying a conductor paste on a support, a ceramic green sheet layer is formed by applying a ceramic slurry on the support on which the conductor layer is formed, a ceramic green sheet with a conductor layer is obtained, through-holes are formed, and the through-holes are filled with the conductor paste (see, for example, Japanese Unexamined Patent Application Publication No. 2006-203185, hereinafter “Patent Document 1”). The support contains an ultraviolet absorbing material, and the through-holes are formed by irradiation with a YAG laser. Also known is a method of machining vias in a ceramic green sheet mounted on a support having an ultraviolet absorptivity of 90% or more (see, for example, Japanese Unexamined Patent Application Publication No. 2009-234074, hereinafter “Patent Document 2”).

### SUMMARY

A pretreatment method for a ceramic plate used for laser beam machining according to an embodiment of the present disclosure includes changing a chroma C* of a ceramic plate material by irradiating the ceramic plate material with ultraviolet light having a wavelength of 300 nm or less.

A manufacturing method for a ceramic substrate according to an embodiment of the present disclosure includes changing a chroma C* of a ceramic plate material by irradiating the ceramic plate material with ultraviolet light having a wavelength of 300 nm or less; and forming a recess or a through-hole by irradiating the ceramic plate, whose chroma C* has been changed by ultraviolet light irradiation, with a laser beam.

A manufacturing method for a light-emitting device according to an embodiment of the present disclosure includes preparing the ceramic substrate manufactured by the manufacturing method for the ceramic substrate according to the present disclosure; and arranging a light-emitting element having an electrode, on the ceramic substrate.

A ceramic plate used for laser beam machining according to an embodiment of the present disclosure is a ceramic plate containing aluminum nitride and including a first portion and a second portion on a same surface. The first portion has a b* value of 3.0 or greater and less than 7.5 in a L*a*b* color system and a chroma C* of 3.0 or greater and less than 7.5. The second portion has a b* value of 7.5 or greater and 12.0 or less in the L*a*b* color system and a chroma C* of 7.5 or greater and 12.0 or less.

A ceramic plate used for laser beam machining according to an embodiment of the present disclosure is a ceramic plate containing silicon nitride and including a first portion and a second portion on a same surface. The first portion has a b* value of 3.0 or greater and less than 16.0 in a L*a*b* color system and a chroma C* of 3.0 or greater and less than 16.0. The second portion has a b* value of 16.0 or greater and 23.0 or less in the L*a*b* color system and a chroma C* of 16.0 or greater and 25.0 or less.

Alight-emitting device according to an embodiment of the present disclosure includes a ceramic plate containing aluminum nitride and including a first portion and a second portion on a same surface, the first portion having a b* value of 3.0 or greater and less than 7.5 in a L*a*b* color system and a chroma C* of 3.0 or greater and less than 7.5, the second portion having a b* value of 7.5 or greater and 12.0 or less in the L*a*b* color system and a chroma C* of 7.5 or greater and 12.0 or less, and a ceramic substrate having a recess or a through-hole arranged in at least any region of the second portion; and a light-emitting element arranged on the ceramic substrate and having an electrode.

A light-emitting device according to an embodiment of the present disclosure includes a ceramic plate containing silicon nitride and including a first portion and a second portion on a same surface, the first portion having a b* value of 3.0 or greater and less than 16.0 in a L*a*b* color system and a chroma C* of 3.0 or greater and less than 16.0, the second portion having a b* value of 16.0 or greater and 23.0 or less in the L*a*b* color system and a chroma C* of 16.0 or greater and 25.0 or less, and a ceramic substrate having a recess or a through-hole arranged in at least any region of the second portion; and a light-emitting element arranged on the ceramic substrate and having an electrode.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic top view illustrating an example of a ceramic plate according to an embodiment of the present disclosure.

FIG. 1B is a perspective view taken along line IB-IB of FIG. 1.

FIG. 2 is a flowchart illustrating an example of a pretreatment method according to an embodiment of the present disclosure.

FIG. 3A is a schematic top view illustrating an example of preparing a ceramic plate material.

FIG. 3B is an enlarged top view of region IIIB of FIG. 3A.

FIG. 3C is a schematic top view illustrating an example of placing a coating film.

FIG. 3D is a schematic top view illustrating an example of changing a chroma C*.

FIG. 3E is a schematic top view illustrating an example of marking.

FIG. 4A is a schematic top view illustrating an example of a ceramic substrate according to Embodiment 2-1.

FIG. 4B is an enlarged top view of region IVB of FIG. 4A.

FIG. 4C is a schematic cross-sectional view in line IVC-IVC of FIG. 4B.

FIG. 4D is an enlarged bottom view corresponding to region IVB of FIG. 4A.

FIG. 5 is a flowchart illustrating an example of a manufacturing method for the ceramic substrate according to Embodiment 2-1.

FIG. 6A is a schematic top view illustrating an example of a ceramic substrate according to Embodiment 2-2.

FIG. 6B is a schematic cross-sectional view along line VIB-VIB of FIG. 6A.

FIG. 7 is a flowchart illustrating an example of a manufacturing method for the ceramic substrate according to Embodiment 2-2.

FIG. 8A is a schematic cross-sectional view illustrating an example of a light-emitting device according to Embodiment 3-1.

FIG. 8B is a schematic cross-sectional view illustrating an example of a light-emitting device according to Embodiment 3-2.

FIG. 9A is a perspective view illustrating an application example of the light-emitting device according to Embodiment 3-1.

FIG. 9B is a cross-sectional view along line IXB-IXB of FIG. 9A.

FIG. 10 is a flowchart illustrating an example of a manufacturing method for a light-emitting device according to an embodiment.

FIG. 11 is a photograph of an observation of color development of a ceramic plate material before irradiation with ultraviolet light and a ceramic plate after irradiation with ultraviolet light in Test Example 1.

FIG. 12 is a graph illustrating the results of measuring the reflectance of the ceramic plate material before irradiation with ultraviolet light and the ceramic plate after irradiation with ultraviolet light in Test Example 3.

### DETAILED DESCRIPTION

Embodiments of the present disclosure can provide a pretreatment method for a ceramic plate that enables simple laser beam machining with a reduced number of steps, a ceramic plate, a light-emitting device, and a manufacturing method for a ceramic substrate and a light-emitting device.

According to one embodiment of the present disclosure, it is possible to provide a pretreatment method for a ceramic plate that enables simple laser beam machining with a reduced number of steps, a ceramic plate, and a light-emitting device, as well as a manufacturing method for a ceramic substrate and a light-emitting device.

A pretreatment method for a ceramic plate, a ceramic plate, a light-emitting device, and a manufacturing method for a ceramic substrate and a light-emitting device according to embodiments of the present disclosure will be described in detail with reference to the drawings. However, the following embodiments are to illustrate a pretreatment method for a ceramic plate, a ceramic plate, a light-emitting device, and a manufacturing method for a ceramic substrate and a light-emitting device in order to realize the technical concept of the present disclosure, and are not limited to the descriptions hereinafter.

The dimensions, materials, shapes, relative arrangements, and the like of the components described in the embodiments are not intended to limit the scope of the present disclosure only to them, and are merely illustrative examples, unless otherwise specified. The sizes, positional relationships, and the like of the members illustrated in the drawings may be exaggerated in order to clarify the description. In the following description, the same names and reference numerals indicate the same or similar members, and the detailed description is omitted as appropriate. In order to avoid excessively complicating the drawings, a schematic drawing in which some elements are omitted is used, or an end view illustrating only a cut surface is used as a sectional view.

In the present disclosure, a polygon such as a rectangle, a triangle, and a quadrilateral is referred to as a polygon including a shape in which processing such as corner rounding, chamfering, squaring, and rounding is applied to the corners of the polygon. Not only a corner (edge of a side) but also a shape in which processing is applied to an intermediate portion of a side is referred to as a polygon. In other words, a shape in which partial processing is applied while leaving a polygon as a base is included in the interpretation of “polygon” described in the present disclosure.

The same applies not only to a polygon but also to a word indicating a specific shape such as a trapezoid, a circle, and an irregularity. The same applies to the case where each side forming the shape is treated. In other words, even if processing is applied to a corner or an intermediate portion of a certain side, the processed portion is included in the interpretation of “side”. When distinguishing a partially unprocessed “polygon” or “side” from a processed shape, “strict” is added, and for example, “strict square” is described.

In the following description, terms indicating specific directions or positions (for example, “top”, “bottom”, “side”, “X”, “Y”, “Z”, and other terms including those terms) are used as necessary. However, the use of these terms is intended to facilitate understanding of the invention with reference to the drawings, and the technical scope of the invention is not excessively limited by the meaning of these terms. For example, when the term “top surface” is used, the invention is not required to always face upward. In the embodiment, the term “covering” is not limited to the case of direct contact, but also includes the case of covering indirectly, for example, through another member.

In the present specification or the claims, when there are a plurality of components and each component is expressed separately, “first”, “second” or the like may be added at the beginning of the component to distinguish it.

### Ceramic Plate for Laser Beam Machining

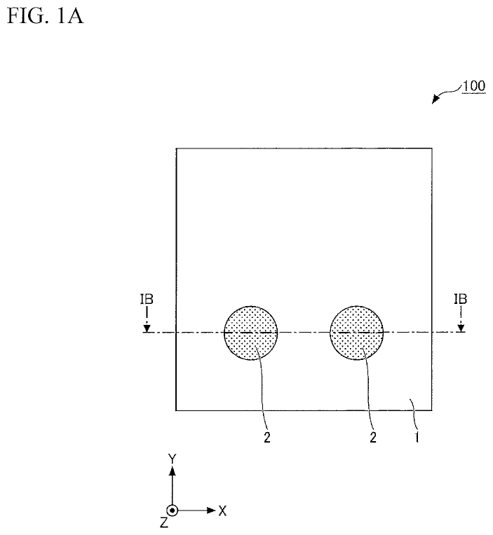

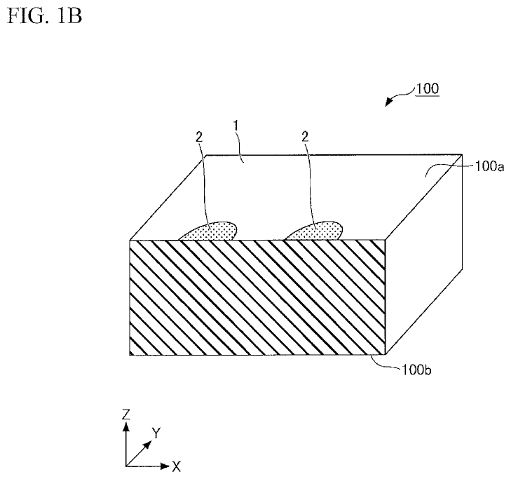

FIG. 1A is a schematic top view illustrating an example of a ceramic plate according to an embodiment of the present disclosure. FIG. 1B is a schematic cross-sectional view taken along line IB-IB in FIG. 1A. A ceramic plate 100 used for laser beam machining according to an embodiment of the present disclosure includes a first portion 1 and a second portion 2 provided on the same surface, the first portion 1 having a specific b* value in a L*a*b* color system and a specific chroma C*, and the second portion 2 having a specific b* value in the L*a*b* color system and a specific chroma C* different from the first portion 1.

The b* value in the L*a*b* color system and the chroma C* of the first portion 1 and those of the second portion 2 have respective specific ranges depending on the material of the ceramic plate.

The ceramic plate 100 is preferably a plate-like member having a rectangular outer shape in a plan view. The rectangle can be a rectangle having a long side and a short side. It is assumed that the rectangle can include a square unless it is specifically mentioned that a square is excluded. The outer shape of the ceramic plate 100 in a plan view is not limited to a rectangle, but can have various shapes, such as a circle, an ellipse, a polygon with rounded corners, or a combination of these shapes.

The shape and size of the ceramic plate 100 in a plan view can be appropriately adjusted according to required performance.

The surface of the ceramic plate 100 having the first portion 1 and the second portion 2 is hereinafter referred to as a “first surface 100a.” The first surface 100a can be flat or non-flat; however, a flat first surface 100a is preferable in that, when the ceramic plate 100 is used in a light-emitting device after laser beam machining, a light-emitting element can be suitably arranged on the ceramic plate 100.

A second surface 100b opposite to the first surface 100a can be flat or non-flat; however, a flat second surface 100b is preferable in that, when the ceramic plate 100 is used in a light-emitting device after laser beam machining, a light-emitting device can be suitably arranged on a mounting substrate.

The first surface 100a and the second surface 100b are parallel, for example. Herein, when “parallel” is described with respect to the surface of the ceramic plate 100, a difference within ±5 degrees is allowed.

The average thickness of the ceramic plate 100 is not particularly limited, but is preferably 100 μm to 1,000 μm, and more preferably 120 μm to 500 km.

The average thickness of the ceramic plate 100 is a value obtained by measuring the thickness of two points freely selected from the corner of the ceramic plate 100 and calculating the average of these points. The thickness of the corner of the ceramic plate 100 is measured using a macro gauge.

### Embodiment 1-1

The ceramic plate 100 according to Embodiment 1-1 is the ceramic plate 100 used for laser beam machining, the ceramic plate 100 containing aluminum nitride and including the first portion 1 and the second portion provided on the same surface, wherein the first portion 1 has a b* value in the L*a*b* color system of 3.0 or greater and less than 7.5 and a chroma C* of 3.0 or greater and less than 7.5, and the second portion 2 has a b* value in the L*a*b* color system of 7.5 or greater and 12.0 or less and a chroma C* of 7.5 or greater and 12.0 or less.

The main material of the ceramic plate 100 according to Embodiment 1-1 is aluminum nitride, and can contain other components as necessary. In the present disclosure, the term “main material of the ceramic plate 100” means a material having the largest amount of material among the materials constituting the ceramic plate 100.

In the present disclosure, the chroma C* is a value calculated from the a* value and b* value in the L*a*b* color system by the following equation. The L*a*b* color system has been standardized by the International Commission on Illumination (CIE) and is also specified in JIS Z 8781-4:2023 “Colorimetry—Part 4: CIE 1976 L*a*b* color space”.

(C*)=\sqrt{(a*)²+(b*)²} Math.1

In the present disclosure, the a* value, b* value, and chroma C* of the ceramic plate 100 mean the a* value, b* value, and chroma C* of the surface (exposed surface) of the ceramic plate 100.

In the ceramic plate 100 according to Embodiment 1-1, the b* value of the first portion 1 is 3.0 or greater and less than 7.5, preferably 4.0 or greater and 7.3 or less, and more preferably 5.0 or greater and 7.3 or less.

In the ceramic plate 100 according to Embodiment 1-1, the chroma C* of the first portion 1 is 3.0 or greater and less than 7.5, preferably 4.0 or greater and 7.3 or less, and more preferably 5.0 or greater and 7.3 or less.

In the ceramic plate 100 according to Embodiment 1-1, the b* value of the second portion 2 is 7.5 or greater and 12.0 or less, preferably 7.5 or greater and 10.0 or less, and more preferably 7.7 or greater and 9.5 or less.

In the ceramic plate 100 according to Embodiment 1-1, the chroma C* of the second portion 2 is 7.5 or greater and 12.0 or less, preferably 7.5 or greater and 10.0 or less, and more preferably 7.7 or greater and 9.5 or less.

The a* value, the b* value, and the chroma C* can be measured by a color difference meter, a spectral densitometer (for example, FD-5 manufactured by Konica Minolta Japan Co., Ltd.), or the like.

In the ceramic plate 100, when the b* value and the chroma C* of the second portion 2 satisfy the above ranges, the reflectance on the surface of the ceramic plate 100 can be reduced and the optical reflection can be suppressed, so that the ceramic plate 100 can easily absorb a laser beam. Therefore, in the ceramic plate 100 used for laser beam machining, the region irradiated with a laser beam is the second portion 2.

The shapes and dimensions of the first portion 1 and the second portion 2 in FIG. 1A are merely examples and are not particularly limited, and can be appropriately adjusted according to a desired laser beam machining region. Therefore, the shapes of the first portion 1 and the second portion 2 can be a shape selected appropriately from a polygon such as a circle, an ellipse, a rectangle, a triangle, or a combination of these shapes.

The number of the first portion 1 and the second portion 2 in the ceramic plate 100 is also not particularly limited, and can be one or two or more. In the present embodiment, the ceramic plate has two second portions 2; however, before singulation, one ceramic plate 100 can have two or more second portions 2.

### Embodiment 1-2

The ceramic plate 100 according to Embodiment 1-2 is a ceramic plate for laser beam machining that contains silicon nitride and includes, on the same surface, a first portion 1 and a second portion 2. The first portion 1 has a b* value in a L*a*b* color system of 3.0 or greater and less than 16.0 and a chroma C* of 3.0 or greater and less than 16.0. The second portion 2 has a b* value in the L*a*b* color system of 16.0 or greater and 23.0 or less and a chroma C* of 16.0 or greater and 25.0 or less.

The ceramic plate 100 according to Embodiment 1-2 is the same as the ceramic plate 100 according to Embodiment 1-1 except that the main material is silicon nitride and the b* value and chroma C* of the first portion 1 and the b* value and chroma C* of the second portion 2 are different.

In the ceramic plate 100 according to Embodiment 1-2, the b* value of the first portion 1 is 3.0 or greater and less than 16.0, preferably 8.0 or greater and 15.0 or less, and more preferably 10.0 or greater and 14.0 or less.

In the ceramic plate 100 according to Embodiment 1-2, the chroma C* of the first portion 1 is 3.0 or greater and less than 16.0, preferably 8.0 or greater and 15.0 or less, and more preferably 10.0 or greater and 14.0 or less.

In the ceramic plate 100 according to Embodiment 1-2, the b* value of the second portion 2 is 16.0 or greater and 23.0 or less, preferably 18.0 or greater and 23.0 or less, and more preferably 19.0 or greater and 23.0 or less.

In the ceramic plate 100 according to Embodiment 1-2, the chroma C* of the second portion 2 is 16.0 or greater and 25.0 or less, preferably 18.0 or greater and 23.0 or less, and more preferably 18.0 or greater and 23.0 or less.

### Pretreatment Method

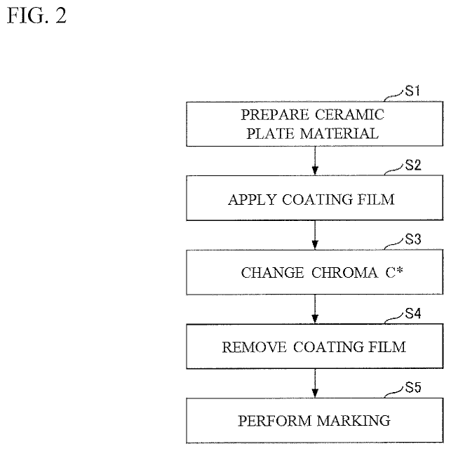

FIG. 2 is a flowchart illustrating an example of a pretreatment method according to an embodiment of the present disclosure. The pretreatment method according to an embodiment of the present disclosure is a pretreatment method for the ceramic plate 100 used for laser beam machining. The pretreatment method includes step S3 of changing the chroma C* by irradiating a ceramic plate material 101 with ultraviolet light having a wavelength of 300 nm or less. The pretreatment method according to an embodiment of the present disclosure preferably further includes step S1 of preparing a ceramic plate material, step S2 of applying a coating film, step S4 of removing the coating film, and can further include other processes, such as step S5 of performing marking, if necessary.

With the pretreatment method according to an embodiment of the present disclosure, the ceramic plate material 101 can be formed into the ceramic plate 100 having the first portion 1 and the second portion 2. Accordingly, the pretreatment method also serves as a manufacturing method for a ceramic plate used for laser beam machining according to an embodiment of the present disclosure.

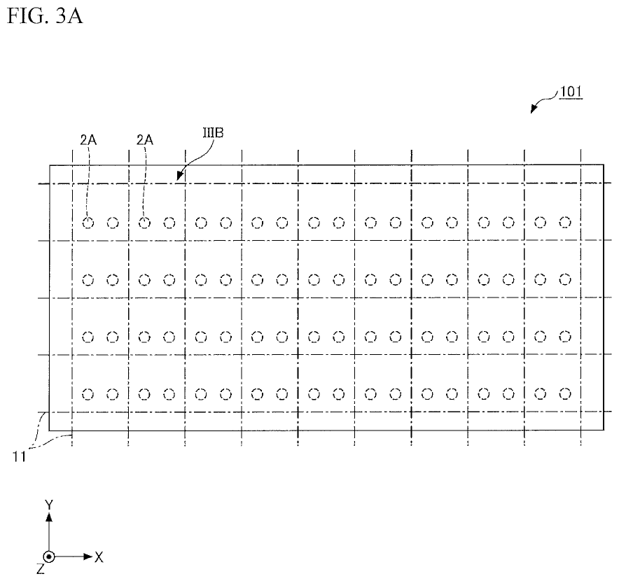

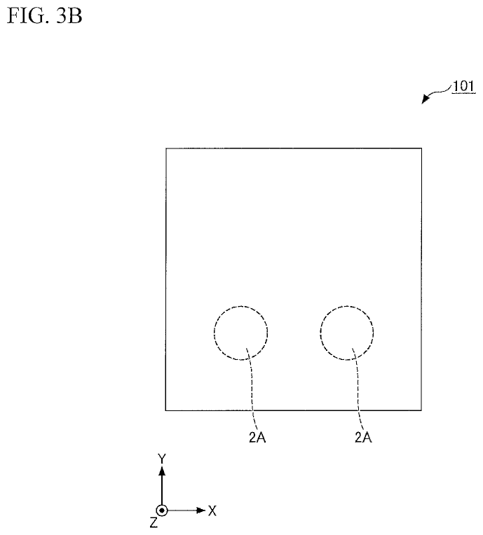

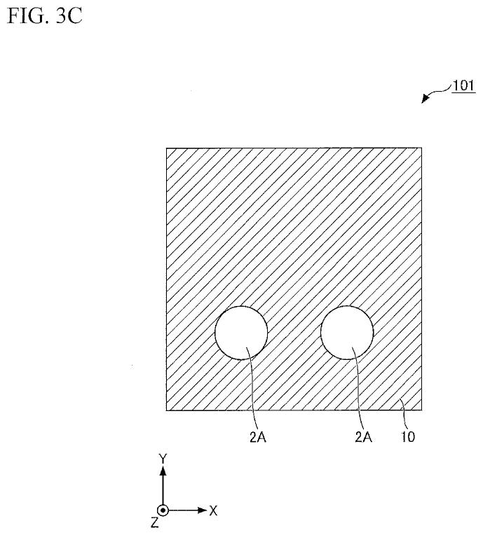

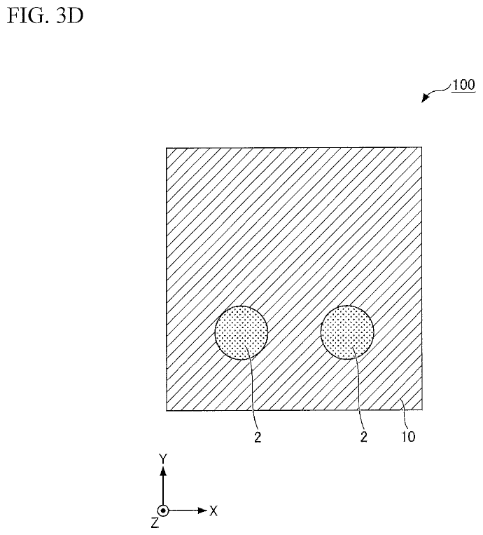

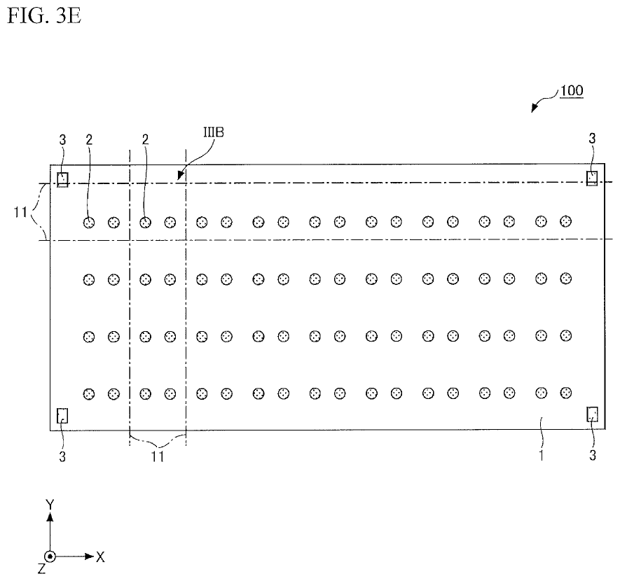

The pretreatment method according to an embodiment of the present disclosure will be described below with reference to FIGS. 3A through 3E. FIGS. 3B through 3D illustrate a state in which one singulated ceramic plate 100 is formed, while FIG. 3A illustrates the ceramic plate material 101 having a plurality of regions 2A to be irradiated with ultraviolet light, and FIG. 3E illustrates a state of the ceramic plate 100 having a plurality of second portions 2. However, FIGS. 3A through 3D illustrate a state before laser beam machining.

### (S1) Preparing a Ceramic Plate Material

FIG. 3A is a schematic top view illustrating an example of preparing a ceramic plate material. FIG. 3B is an enlarged top view of region IIIB in FIG. 3A. In step S1 of preparing a ceramic plate material, the ceramic plate material 101 is prepared.

In the drawings, for the sake of convenience of illustration, on one surface of the ceramic plate material 101, the regions 2A to be irradiated with ultraviolet light in step S3 of changing the chroma C* and cutting lines 11 for cutting the ceramic plate material 101 into a shape suitable for the ceramic substrate 200, are indicated by broken lines. However, the shape, pattern, size, and the like of the regions 2A to be irradiated with ultraviolet light and the cutting lines 11 are not limited to those illustrated, and can be appropriately adjusted according to the required performance of the ceramic substrate 200.

The ceramic plate material 101 is an insulating member made of a ceramic material. The ceramic plate material 101 can be a ceramic precursor in a softened state before sintering or a sintered ceramic. However, a sintered ceramic is preferable because it exhibits smaller dimensional variation due to sintering, thereby enabling accurate machining at desired positions by laser beam machining, such as the formation of through-holes or recesses, and allowing the sizes of the through-holes or recesses to be adjusted to predetermined desired sizes.

The ceramic plate material 101 is not particularly limited and can be suitably selected according to the purpose, but preferably contains at least any one selected from the group consisting of aluminum nitride, silicon nitride, aluminum oxide, and boron nitride, and more preferably contains, as a main material, any one selected from the group consisting of aluminum nitride, silicon nitride, aluminum oxide, and boron nitride. The ceramic plate material 101 can be a commercially available product.

The sub-material other than the main material of the first portion 1 and the second portion 2 is not particularly limited and can include, for example, a ceramic material other than the main material and glass.

Ceramic materials other than the main material are not particularly limited and can include, for example, oxide-based ceramic materials (e.g., silicon oxide, calcium oxide, and magnesium oxide), silicon carbide, mullite, borosilicate glass, and the like. One of these can be used alone, or two or more can be used in combination.

For example, the ceramic plate 100 according to Embodiment 1-1 can be manufactured using the ceramic plate material 101 containing aluminum nitride as a main material, the ceramic plate material 101 having a b* value in the L*a*b* color system of 3.0 or greater and less than 7.5 and a chroma C* of 3.0 or greater and less than 7.5.

For example, the ceramic plate 100 according to Embodiment 1-2 can be manufactured using the ceramic plate material 101 containing silicon nitride as a main material, the ceramic plate material 101 having a b* value in the L*a*b* color system of 3.0 or greater and less than 16.0 and a chroma C* of 3.0 or greater and less than 16.0.

For example, the ceramic plate material 101 containing aluminum oxide as a main material and having a b* value in the L*a*b* color system of 0.1 or greater and 1.0 or less and a chroma C* of 0.1 or greater and 1.0 or less can be used.

For example, the ceramic plate material 101 containing boron nitride as a main material and having a b* value in the L*a*b* color system of 1.0 or greater and less than 4.5, and a chroma C* of 1.0 or greater and less than 4.5 can be used.

Step S1 of preparing a ceramic plate material can include machining a non-plate-like ceramic material into a desired plate-like shape. Ceramic materials can be machined using, for example, a disc-shaped rotary blade, an ultrasonic cutter, a laser beam irradiation blade, or the like.

### (S2) Applying a Coating Film

FIG. 3B is a schematic top view illustrating an example of applying a coating film. In step S2 of applying a coating film, a coating film 10 having a desired shape is applied to the ceramic plate material 101.

When the coating film 10 having a desired shape is applied to the ceramic plate material 101, the surface of the ceramic plate material 101 is exposed in a region where the coating film 10 is not applied. The exposed portion of the ceramic plate material 101 is irradiated with ultraviolet light having a wavelength of 300 nm or less in step S3 of changing the chroma C*. In other words, a region where the surface of the ceramic plate material 101 where the coating film 10 is not applied is the region 2A to be irradiated with ultraviolet light.

The coating film 10 is not particularly limited as long as it does not transmit or is difficult to transmit ultraviolet light having a wavelength of 300 nm or less, and can be suitably selected from known materials, such as resin films and metal films. The coating film is difficult to transmit ultraviolet light having a wavelength of 300 nm or less, as long as it reflects or absorbs 50% or more, preferably 70% or more, of the radiated ultraviolet light.

The shape and size of the coating film 10 are also not particularly limited, and can be suitably adjusted according to a desired region 2A to be irradiated with ultraviolet light in step S3 of changing the chroma C*.

### (S3) Changing the Chroma C*

FIG. 3D is a schematic top view illustrating an example of changing the chroma C*. In step S3 of changing the chroma C*, the region 2A to be irradiated with ultraviolet light in the ceramic plate material 101 is irradiated with ultraviolet light having a wavelength of 300 nm or less (hereinafter, sometimes simply abbreviated as “ultraviolet light”) to change the chroma C* of the ceramic plate material 101. In step S3 of changing the chroma C*, the ceramic plate material 101 becomes a ceramic plate 100 having the first portion 1 and the second portion 2.

By being subjected to step S3 of changing the chroma C*, the region where the coating film 10 is applied is rendered the first portion 1, and the region 2A to be irradiated with ultraviolet light, in which the coating film 10 is not applied, is rendered the second portion 2. In other words, by step S3 of changing the chroma C*, the region in which the coating film 10 is applied on the ceramic plate material 101 and which is not irradiated with ultraviolet light is defined as the first portion 1, and the region in which the coating film 10 is not applied on the ceramic plate material 101 and which is irradiated with ultraviolet light is defined as the second portion 2.

The wavelength of ultraviolet light in step S3 of changing the chroma C* is not particularly limited as long as the wavelength is 300 nm or less, but it is preferably 10 nm to 300 nm, and more preferably 200 nm to 300 nm. When the wavelength of ultraviolet light in step S3 of changing the chroma C* is 300 nm or less, the chroma C* of the ceramic plate material 101 can be efficiently changed.

The irradiation with ultraviolet light in step S3 of changing the chroma C* can be performed by using a known ultraviolet lamp, such as a xenon lamp, a deuterium lamp, a mercury lamp, a UV-LED, a laser-excited white light source, and the like.

The irradiance of ultraviolet light in step S3 of changing the chroma C* is not particularly limited, but it is preferably 0.1 mW/cm² or more, more preferably 0.4 mW/cm² or more, and still more preferably 1.0 mW/cm² or more. The upper limit of the irradiance of ultraviolet light in step S3 of changing the chroma C* is also not particularly limited, but it is preferably 10 mW/cm² or less. When the irradiance of ultraviolet light in step S3 of changing the chroma C* is 0.1 mW/cm² or more, the chroma C* of the ceramic plate material 101 can be efficiently changed.

The irradiation time of the irradiation with ultraviolet light in step S3 of changing the chroma C* is not particularly limited, but preferably ten minutes or less, more preferably seven minutes or less, and still more preferably five minutes or less. The lower limit value of the irradiation time of the irradiation with ultraviolet light in step S3 of changing the chroma C* is also not particularly limited, but preferably one minute or more. When the irradiation time of the irradiation with ultraviolet light in step S3 of changing the chroma C* is ten minutes or less, efficient change of the chroma C* of the ceramic plate material 101 can be achieved. In step S3 of changing the chroma C*, there is an integral relationship between the irradiance of ultraviolet light and the irradiation time, and the same effect can be obtained by shortening the irradiation time when the irradiance is high and increasing the irradiation time when the irradiance is low.

In the present disclosure, a change in the chroma C* of the ceramic plate material 101 means that the chroma C* of the ceramic plate 100 after irradiation with ultraviolet light is different from the chroma C* of the ceramic plate material 101 before irradiation with ultraviolet light. This change in the chroma C* before and after irradiation with ultraviolet light means that the chroma C* after irradiation is greater than the chroma C* before irradiation. By increasing the chroma C*, the reflectance at the surface of the ceramic plate 100 is reduced, thereby suppressing optical reflection. As a result, the ceramic plate 100 can more easily absorb a laser beam, enabling through-holes to be formed efficiently.

The change in the chroma C* of the ceramic plate material 101 can be appropriately selected by the ceramic plate material 101. Although the chroma C* of the ceramic plate 100 after irradiation with ultraviolet light can vary between the chroma C* immediately after irradiation with ultraviolet light and 100 hours after the end of irradiation, the chroma C* of the ceramic plate 100 after irradiation is still greater than the chroma C* of the ceramic plate material 101 before irradiation.

In the present disclosure, “immediately after irradiation” with ultraviolet light means within fifteen minutes after the end of irradiation, and preferably within one to fifteen minutes.

In step S3 of changing the chroma C*, it is preferable that the b* value of the ceramic plate 100 after irradiation with ultraviolet light also changes as compared with the b* value of the ceramic plate material 101 before irradiation with ultraviolet light.

In the present disclosure, a change in the b* value of the ceramic plate material 101 means that the b* value of the ceramic plate 100 after irradiation with ultraviolet light is different from the b* value of the ceramic plate material 101 before irradiation with ultraviolet light. This change in the b* value before and after irradiation with ultraviolet light means that the b* value after irradiation is greater than the b* value before irradiation. By increasing the b* value, the reflectance at the surface of the ceramic plate 100 is reduced, thereby suppressing optical reflection. As a result, the ceramic plate 100 can more easily absorb a laser beam, enabling through-holes to be formed efficiently.

The change in the b* value of the ceramic plate material 101 can be appropriately selected by the ceramic plate material 101. Although the b* value of the ceramic plate 100 after irradiation with ultraviolet light can vary between the b* value immediately after irradiation with ultraviolet light and 100 hours after the end of irradiation, the b* value of the ceramic plate 100 after irradiation is still greater than the b* value of the ceramic plate material 101 before irradiation.

Specific examples of the chroma C* and the b* value in step S3 of changing the chroma C* will be described below.

When the ceramic plate material 101 is aluminum nitride, in step S3 of changing the chroma C* by irradiation with ultraviolet light, it is preferable that:
(i) the ceramic plate material 101 before irradiation with ultraviolet light have a b* value in the L*a*b* color system of less than 7.5 and a chroma C* of less than 7.5;
(ii) the ceramic plate 100 immediately after irradiation with ultraviolet light have a b* value in the L*a*b* color system of 15.0 or greater and a chroma C* of 15.0 or greater; and
(iii) the ceramic plate 100 100 hours after the end of irradiation with ultraviolet light have a b* value in the L*a*b* color system of 7.5 or greater and a chroma C* of 7.5 or greater.

When the ceramic plate material 101 is aluminum nitride, in step S3 of changing the chroma C* by irradiation with ultraviolet light, it is more preferable that:
(i) the ceramic plate material 101 before irradiation with ultraviolet light have a b* value of 3.0 or greater and less than 7.5 and a chroma C* of 3.0 or greater and less than 7.5;
(ii) the ceramic plate 100 immediately after irradiation with ultraviolet light have a b* value of 15.0 or greater and 30.0 or less and a chroma C* of 15.0 or greater and 30.0 or less; and
(iii) the ceramic plate 100 100 hours after the end of irradiation with ultraviolet light have a b* value of 7.5 or greater and 12.0 or less and a chroma C* of 7.5 or greater and 12.0 or less.

When the ceramic plate material 101 is aluminum nitride, in step S3 of changing the chroma C* by irradiation with ultraviolet light, it is still more preferable that:
(i) the ceramic plate material 101 before irradiation with ultraviolet light have a b* value of 4.0 or greater and 7.3 or less and a chroma C* of 4.0 or greater and 7.3 or less;
(ii) the ceramic plate 100 immediately after irradiation with ultraviolet light have a b* value of 18.0 or greater and 28.0 or less and a chroma C* of 18.0 or greater and 29.0 or less; and
(iii) the ceramic plate 100 100 hours after the end of irradiation with ultraviolet light have a b* value of 7.5 or greater and 10.0 or less and a chroma C* of 7.5 or greater and 10.0 or less.

When the ceramic plate material 101 is aluminum nitride, in step S3 of changing the chroma C* by irradiation with ultraviolet light, it is particularly more preferable that:
(i) the ceramic plate material 101 before irradiation with ultraviolet light have a b* value of 5.0 or greater and 7.3 or less and a chroma C* of 5.0 or greater and 7.3 or less;
(ii) the ceramic plate 100 immediately after irradiation with ultraviolet light have a b* value of 19.0 or greater and 27.0 or less and a chroma C* of 19.0 or greater and 28.5 or less; and
(iii) the ceramic plate 100 100 hours after the end of irradiation with ultraviolet light have a b* value of 7.7 or greater and 9.5 or less and a chroma C* of 7.7 or greater and 9.5 or less.

When the ceramic plate material 101 is silicon nitride, in step S3 of changing the chroma C* by irradiation with ultraviolet light, it is preferable that:
(i) the ceramic plate material 101 before irradiation with ultraviolet light have a b* value in the L*a*b* color system of 16.0 or less and a chroma C* of 16.0 or less;
(ii) the ceramic plate 100 immediately after irradiation with ultraviolet light have a b* value in the L*a*b* color system of 18.0 or greater and a chroma C* of 18.0 or greater; and
(iii) the ceramic plate 100 100 hours after the end of irradiation with ultraviolet light have a b* value in the L*a*b* color system of 18.0 or greater and a chroma C* of 18.0 or greater.

When the ceramic plate material 101 is silicon nitride, in step S3 of changing the chroma C* by irradiation with ultraviolet light, it is more preferable that:
(i) the ceramic plate material 101 before irradiation with ultraviolet light have a b* value of 3.0 or greater and less than 16.0 and a chroma C* of 3.0 or greater and less than 16.0;
(ii) the ceramic plate 100 immediately after irradiation with ultraviolet light have a b* value of 16.0 or greater and 23.0 or less and a chroma C* of 16.0 or greater and 25.0 or less; and
(iii) the ceramic plate 100 100 hours after the end of irradiation with ultraviolet light have a b* value of 16.0 or greater and 23.0 or less and a chroma C* of 16.0 or greater and 25.0 or less.

When the ceramic plate material 101 is silicon nitride, in step S3 of changing the chroma C* by irradiation with ultraviolet light, it is still more preferable that:
(i) the ceramic plate material 101 before irradiation with ultraviolet light have a b* value of 8.0 or greater and 15.0 or less and a chroma C* of 8.0 or greater and 15.0 or less;
(ii) the ceramic plate 100 immediately after irradiation with ultraviolet light have a b* value of 18.0 or greater and 23.0 or less and a chroma C* of 18.0 or greater and 23.0 or less; and
(iii) the ceramic plate 100 100 hours after the end of irradiation with ultraviolet light have a b* value of 18.0 or greater and 23.0 or less and a chroma C* of 18.0 or greater and 23.0 or less

When the ceramic plate material 101 is silicon nitride, in step S3 of changing the chroma C* by irradiation with ultraviolet light, it is particularly more preferable that:
(i) the ceramic plate material 101 before irradiation with ultraviolet light have a b* value of 10.0 or greater and 14.0 or less and a chroma C* of 5.0 or greater and 7.3 or less;
(ii) the ceramic plate 100 immediately after irradiation with ultraviolet light have a b* value of 19.0 or greater and 27.0 or less and a chroma C* of 19.0 or greater and 28.5 or less; and
(iii) the ceramic plate 100 100 hours after the end of irradiation with ultraviolet light have a b* value of 19.0 or greater and 23.0 or less and a chroma C* of 18.0 or greater and 23.0 or less.

When the ceramic plate material 101 is aluminum oxide, in step S3 of changing the chroma C* by irradiation with ultraviolet light, it is preferable that:
(i) the ceramic plate material 101 before irradiation with ultraviolet light have a b* value in the L*a*b* color system of 1.0 or less and a chroma C* of 1.0 or less;
(ii) the ceramic plate 100 immediately after irradiation with ultraviolet light have a b* value in the L*a*b* color system of greater than 1.0 and a chroma C* of greater than 1.0; and
(iii) the ceramic plate 100 100 hours after the end of irradiation with ultraviolet light have a b* value in the L*a*b* color system of greater than 1.0 and a chroma C* of greater than 1.0.

When the ceramic plate material 101 is aluminum oxide, in step S3 of changing the chroma C* by irradiation with ultraviolet light, it is more preferable that:
(i) the ceramic plate material 101 before irradiation with ultraviolet light have a b* value of 0.1 or greater and 1.0 or less and a chroma C* of 0.1 or greater and 1.0 or less;
(ii) the ceramic plate 100 immediately after irradiation with ultraviolet light have a b* value of greater than 1.0 and less than 5.0 and a chroma C* of greater than 1.0 and less than 5.0;
(iii) the ceramic plate 100 100 hours after the end of irradiation with ultraviolet light have a b* value of greater than 1.0 and less than 5.0 and a chroma C* of greater than 1.0 and less than 5.0.

When the ceramic plate material 101 is aluminum oxide, in step S3 of changing the chroma C* by irradiation with ultraviolet light, it is still more preferable that:
(i) the ceramic plate material 101 before irradiation with ultraviolet light have a b* value of 0.1 or greater and 0.8 or less and a chroma C* of 0.1 or greater and 0.8 or less;
(ii) the ceramic plate 100 immediately after irradiation with ultraviolet light have a b* value of 1.5 or greater and 5.0 or less and a chroma C* of 1.5 or greater and 5.0 or less; and
(iii) the ceramic plate 100 100 hours after the end of irradiation with ultraviolet light have a b* value of 1.5 or greater and 5.0 or less and a chroma C* of 1.5 or greater and 5.0 or less.

When the ceramic plate material 101 is aluminum oxide, in step S3 of changing the chroma C* by irradiation with ultraviolet light, it is particularly more preferable that:
(i) the ceramic plate material 101 before irradiation with ultraviolet light have a b* value of 0.1 or greater and 0.5 or less and a chroma C* of 0.1 or greater and 0.5 or less;
(ii) the ceramic plate 100 immediately after irradiation with ultraviolet light have a b* value of 2.0 or greater and 4.0 or less and a chroma C* of 2.0 or greater and 4.0 or less; and
(iii) the ceramic plate 100 100 hours after the end of irradiation with ultraviolet light have a b* value of 2.0 or greater and 4.0 or less and a chroma C* of 2.0 or greater and 4.0 or less.

When the ceramic plate material 101 is boron nitride, in step S3 of changing the chroma C* by irradiation with ultraviolet light, it is preferable that:
(i) the ceramic plate material 101 before irradiation with ultraviolet light have a b* value in the L*a*b* color system of 4.5 or less and a chroma C* of 4.5 or less;
(ii) the ceramic plate 100 immediately after irradiation with ultraviolet light have a b* value in the L*a*b* color system of 4.5 or greater and a chroma C* of 4.5 or greater; and
(iii) the ceramic plate 100 100 hours after the end of irradiation with ultraviolet light have a b* value in the L*a*b* color system of 4.5 or greater and a chroma C* of 4.5 or greater.

When the ceramic plate material 101 is boron nitride, in step S3 of changing the chroma C* by irradiation with ultraviolet light, it is more preferable that:
(i) the ceramic plate material 101 before irradiation with ultraviolet light have a b* value of 1.0 or greater and less than 4.5 and a chroma C* of 1.0 or greater and less than 4.5;
(ii) the ceramic plate 100 immediately after irradiation with ultraviolet light have a b* value of 4.5 or greater and 6.5 or less and a chroma C* of 4.5 or greater and 6.5 or less;
(iii) the ceramic plate 100 100 hours after the end of irradiation with ultraviolet light have a b* value of 4.5 or greater and 6.5 or less and a chroma C* of 4.5 or greater and 6.5 or less.

When the ceramic plate material 101 is boron nitride, in step S3 of changing the chroma C* by irradiation with ultraviolet light, it is still more preferable that:
(i) the ceramic plate material 101 before irradiation with ultraviolet light have a b* value of 2.0 or greater and less than 4.5 and a chroma C* of 2.0 or greater and less than 4.5;
(ii) the ceramic plate 100 immediately after irradiation with ultraviolet light have a b* value of 4.5 or greater and 6.0 or less and a chroma C* of 4.5 or greater and 6.0 or less; and
(iii) the ceramic plate 100 100 hours after the end of irradiation with ultraviolet light have a b* value of 4.5 or greater and 6.0 or less and a chroma C* of 4.5 or greater and 6.0 or less.

When the ceramic plate material 101 is boron nitride, in step S3 of changing the chroma C* by irradiation with ultraviolet light, it is particularly more preferable that:
(i) the ceramic plate material 101 before irradiation with ultraviolet light have a b* value of 2.0 or greater and 4.0 or less and a chroma C* of 2.0 or greater and 4.0 or less;
(ii) the ceramic plate 100 immediately after irradiation with ultraviolet light have a b* value of 4.5 or greater and 5.5 or less and a chroma C* of 4.5 or greater and 5.5 or less; and
(iii) the ceramic plate 100 100 hours after the end of irradiation with ultraviolet light have a b* value of 4.5 or greater and 5.5 or less and a chroma C* of 4.5 or greater and 5.5 or less.

### (S4) Removing the Coating Film

In step S4 of removing the coating film, the coating film 10 is removed from the ceramic plate 100. As a result, the state illustrated in FIGS. 1A and 1B is obtained.

The method of removing the coating film 10 is not particularly limited and can be suitably selected in accordance with the type of the coating film 10.

By step S4 of removing the coating film, the first portion 1 covered with the coating film 10 is exposed. By the steps described above, the ceramic plate 100 used for laser beam machining having the first portion 1 and the second portion 2 on the same surface is obtained.

### (S5) Performing Marking

FIG. 3E is a schematic top view illustrating an example of marking. In step S5 of performing marking, marks 3 are formed on the outer peripheral portion of the ceramic plate 100 having a plurality of second portions 2.

The marks 3 can be formed by repeating step S2 of applying a coating film, step S3 of changing the chroma C*, and step S4 of removing the coating film, with the exception that the shape of the openings in the coating film 10 is set to a desired size and shape of mark formation regions, rather than to the shape of the openings in the coating film 10 to the size and shape of the regions 2A to be irradiated with ultraviolet light.

The second portion 2 and the marks 3 can be simultaneously formed by providing openings corresponding to both the regions 2A to be irradiated with ultraviolet light and the mark formation regions in the coating film 10, and performing steps S2, S3, and S4 once each.

The marks 3 have the same chroma C* and b* values as the second portion 2. Therefore, step S5 of performing marking can be used for positioning the ceramic plate 100 or for trial irradiation during laser beam machining.

### Embodiment 2-1

### Ceramic Substrate

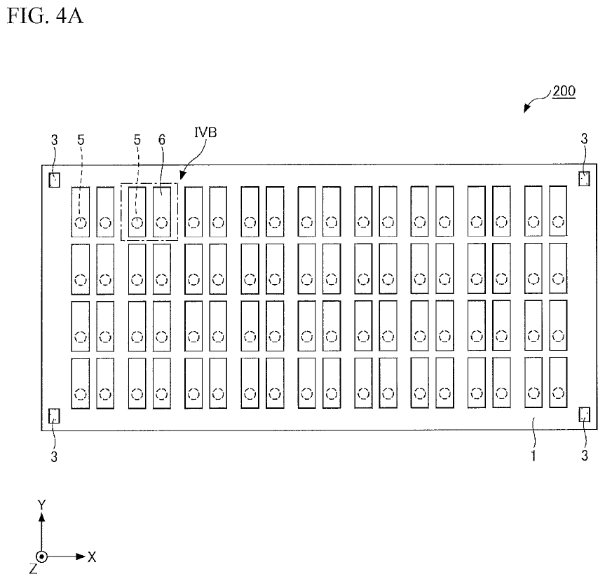

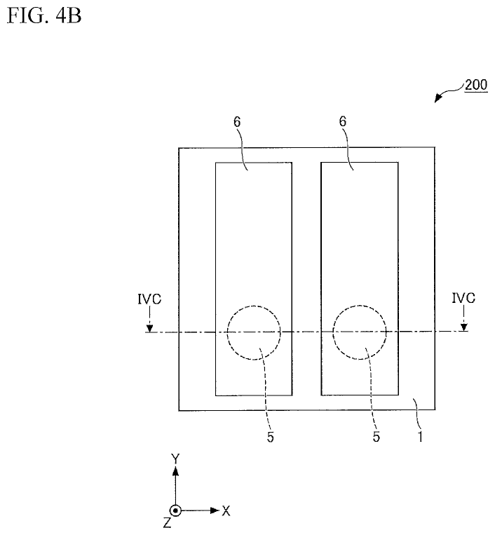

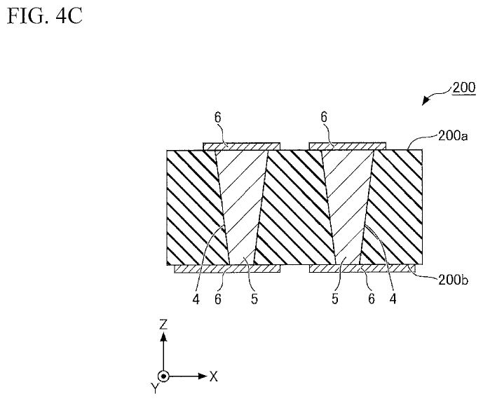

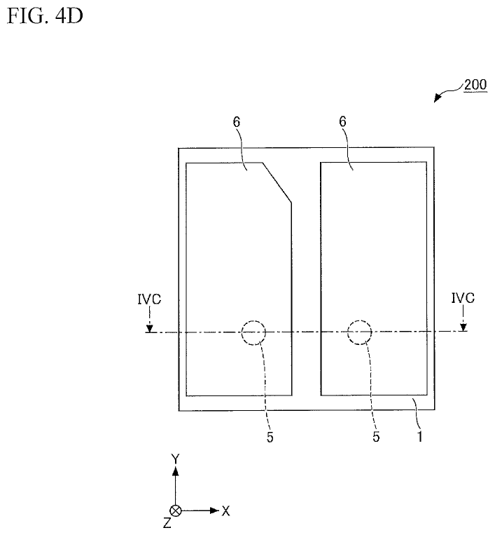

FIG. 4A is a schematic top view illustrating an example of a ceramic substrate according to Embodiment 2-1. FIG. 4B is an enlarged top view of region IVB of FIG. 4A. FIG. 4C is a schematic cross-sectional view taken along line IVC-IVC of FIG. 4B. FIG. 4C is also a schematic cross-sectional view taken along line IVC-IVC of FIG. 4D. FIG. 4D is an enlarged bottom view corresponding to region IVB of FIG. 4A. The ceramic substrate 200 according to Embodiment 2-1 includes a first surface 200a, a second surface 200b opposite to the first surface 200a, the first portion 1, and through-holes 4. It is preferable that the ceramic substrate 200 further include the marks 3, first conductive members 5, and second conductive members 6.

### First Portion 1 and Marks 3

The ceramic substrate 200 has the first portion 1 and the marks 3 on the first surface 200a. The first portion 1 and the second portion 2 are formed from the ceramic plate material 101. The ceramic plate material 101 of the first portion 1 and the second portion 2 is not particularly limited, and for example, the ceramic plate material 101 described in [Pretreatment Method] can be used. It is particularly preferable that the same ceramic material be used as a main material for the first portion 1 and the marks 3.

The first portion 1 and the marks 3 each have a different chroma C*. The chroma C* of the first portion 1 and the marks 3 can be appropriately selected depending on the main material, as will be described in detail in Embodiments 2-1A through 2-1D. The difference in chroma C* between the first portion 1 and the marks 3 formed from the same main material arises from the manufacturing method for the ceramic substrate 200.

### Through-Hole 4

The through-hole 4 connects the first surface 200a and the second surface 200b of the ceramic substrate 200. The cross-sectional shape of the through-hole 4 is not particularly limited, and can be a straight shape in which the opening diameter is constant from the first surface 200a to the second surface 200b, or a tapered shape in which the opening diameter is gradually reduced from the first surface 200a to the second surface 200b. Among these, the cross-sectional shape of the through-hole 4 is preferably the aforementioned tapered shape.

The shape, size, and number of the through-hole 4 in the ceramic substrate 200 are not particularly limited, and can be suitably selected according to the purpose of use of the ceramic substrate 200.

The ceramic substrate 200 can be suitably used as an interconnect substrate. When the ceramic substrate 200 is used as an interconnect substrate, the through-hole 4 can be used as a via.

### First Conductive Member 5

The first conductive member 5 is arranged inside the through-hole 4. The composition of the first conductive member 5 is not particularly limited as long as it has conductivity, and can be suitably selected from known conductive materials, such as metals such as copper (Cu), chromium (Cr), nickel (Ni), silver (Ag), aluminum (Al), zinc (Zn), tin (Sn), and an Ag—Cu alloy. One of these can be used alone, or two or more can be used in combination. Among these, the first conductive member 5 is preferably a Cu layer composed of Cu and an Ag—Cu alloy layer composed of an Ag—Cu alloy.

### Second Conductive Member 6

The second conductive members 6 are arranged on the first surface 200a and the second surface 200b so as to be in contact with the first conductive members 5. The composition of the second conductive members 6 is not particularly limited as long as it has conductivity, and can be suitably selected from known conductive materials, for example, metals such as copper (Cu), chromium (Cr), nickel (Ni), silver (Ag), aluminum (Al), zinc (Zn), tin (Sn), and an Ag—Cu alloy. One of these can be used alone, or two or more can be used in combination. Among these, the second conductive member 6 is preferably a Cu layer composed of Cu and an Ag—Cu alloy layer composed of an Ag—Cu alloy.

The average thickness of the second conductive member 6 is not particularly limited, but is preferably 0.01 μm or greater and 500 μm or less, and more preferably 0.1 μm or greater and 300 μm or less. When the average thickness of the second conductive member 6 is 0.01 μm or greater, adhesion and strength between the second surface 200b of the ceramic substrate 200 and an interconnect board portion 304 are improved, and breakage of the interconnect can be prevented. When the average thickness of the second conductive member 6 is 500 μm or less, the time and cost required to form the second conductive member 6 are reduced, and design changes resulting from expansion of the line and space (L/S) of the interconnect are less likely to occur.

The thickness of the second conductive member 6 can be measured, for example, by X-ray fluorescence, a metal microscope, a microscope, a scanning electron microscope (SEM), or the like. Measurement of the thickness of the second conductive member 6 by one or two or more of these methods is performed at three points freely selected from among the second conductive members 6, and an average value of the thicknesses of the three points is determined to be the average thickness of the second conductive member 6. Measurement of the thickness of the second conductive member 6 by X-ray fluorescence can be performed without destroying the ceramic substrate 200. When measuring the thickness of the second conductive member 6 by a metal microscope, a microscope, a scanning electron microscope (SEM), or the like, the ceramic substrate 200 is polished or ground along the Y-axis direction, a sample having an XZ plane exposed is prepared, and the thickness of the second conductive member 6 along the Z-axis of the exposed XZ plane is measured.

### Embodiment 2-1A

Embodiment 2-1A is a ceramic substrate 200 in which the first portion 1 and the marks 3 are made of aluminum nitride.

### First Portion 1

The chroma C* of the first portion 1 of the ceramic substrate 200 according to Embodiment 2-1A is 3.0 or greater and less than 7.5, preferably 4.0 or greater and 7.3 or less, and more preferably 5.0 or greater and 7.3 or less.

The b* value of the first portion 1 of the ceramic substrate 200 according to Embodiment 2-1A is not particularly limited, but is preferably 3.0 or greater and less than 7.5, more preferably 4.0 or greater and 7.3 or less, and still more preferably 5.0 or greater and 7.3 or less.

### Marks 3

The chroma C* of the marks 3 of the ceramic substrate 200 according to Embodiment 2-1A is 7.5 or greater and 12.0 or less, preferably 7.5 or greater and 10.0 or less, and more preferably 7.7 or greater and 9.5 or less.

The b* value of the marks 3 of the ceramic substrate 200 according to Embodiment 2-1 A is not particularly limited, but is preferably 7.5 or greater and 12.0 or less, more preferably 7.5 or greater and 10.0 or less, and still more preferably 7.7 or greater and 9.5 or less.

### Embodiment 2-1B

Embodiment 2-1B is a ceramic substrate 200 in which the first portion 1 and the marks 3 are made of silicon nitride.

### First Portion 1

The chroma C* of the first portion 1 of the ceramic substrate 200 according to Embodiment 2-1B is 3.0 or greater and less than 16.0, preferably 8.0 or greater and 15.0 or less, and more preferably 10.0 or greater and 14.0 or less.

The b* value of the first portion 1 of the ceramic substrate 200 according to Embodiment 2-1B is not particularly limited, but is preferably 3.0 or greater and less than 16.0, more preferably 8.0 or greater and 15.0 or less, and still more preferably 10.0 or greater and 14.0 or less.

### Marks 3

The chroma C* of the marks 3 of the ceramic substrate 200 according to Embodiment 2-1B is 16.0 or greater and 25.0 or less, preferably 18.0 or greater and 23.0 or less, and more preferably 18.0 or greater and 23.0 or less.

The b* value of the marks 3 of the ceramic substrate 200 according to Embodiment 2-1B is not particularly limited, but is preferably 16.0 or greater and 23.0 or less, more preferably 18.0 or greater and 23.0 or less, and still more preferably 18.0 or greater and 23.0 or less.

### Embodiment 2-1C

Embodiment 2-1C is a ceramic substrate 200 in which the first portion 1 and the marks 3 are made of aluminum oxide.

### First Portion 1

The chroma C* of the first portion 1 of the ceramic substrate 200 according to Embodiment 2-1C is 0.1 or greater and 1.0 or less, preferably 0.1 or greater and 0.8 or less, and more preferably 0.5 or less.

The b* value of the first portion 1 of the ceramic substrate 200 according to Embodiment 2-1C is not particularly limited, but is preferably 0.1 or greater and 1.0 or less, more preferably 0.8 or less, and still more preferably 0.5 or less.

### Marks 3

The chroma C* of the marks 3 of the ceramic substrate 200 according to Embodiment 2-1C is greater than 1.0 and 5.0 or less, preferably 1.5 or greater and 5.0 or less, and still more preferably 2.0 or greater and 4.0 or less.

The b* value of the marks 3 of the ceramic substrate 200 according to Embodiment 2-1C is not particularly limited, but is preferably greater than 1.0 and 5.0 or less, more preferably 1.5 or greater and 5.0 or less, and still more preferably 2.0 or greater and 4.0 or less.

### Embodiment 2-1D

Embodiment 2-1D is a ceramic substrate 200 in which the first portion 1 and the marks 3 are made of boron nitride.

### First Portion 1

The chroma C* of the first portion 1 of the ceramic substrate 200 according to Embodiment 2-1D is 1.0 or greater and less than 4.5, preferably 2.0 or greater and less than 4.5, and more preferably 2.0 or greater and 4.0 or less.

The b* value of the first portion 1 of the ceramic substrate 200 according to Embodiment 2-1D is not particularly limited, but is preferably 1.0 or greater and less than 4.5, more preferably 2.0 or greater and less than 4.5, and still more preferably 2.0 or greater and 4.0 or less.

### Marks 3

The chroma C* of the marks 3 of the ceramic substrate 200 according to Embodiment 2-1D is 4.5 or greater and 6.5 or less, preferably 6.0 or less, and more preferably 5.5 or less.

The b* value of the marks 3 of the ceramic substrate 200 according to Embodiment 2-1D is not particularly limited, but is preferably 4.5 or greater and 6.5 or less, more preferably 4.5 or greater and 6.0 or less, and still more preferably 4.5 or greater and 5.5 or less.

### Manufacturing Method for Ceramic Substrate

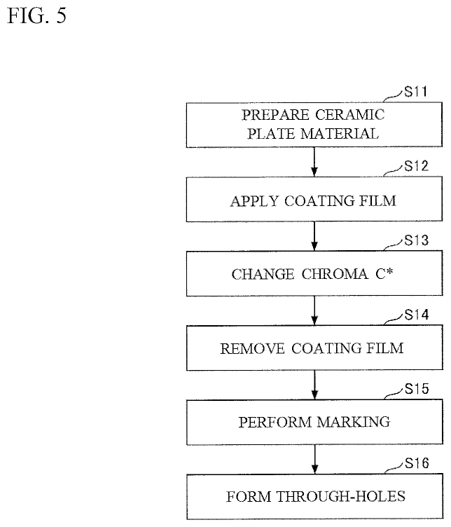

FIG. 5 is a flowchart illustrating an example of a manufacturing method for the ceramic substrate according to Embodiment 2-1. The manufacturing method for the ceramic substrate according to Embodiment 2-1 includes: step S13 of changing the chroma C* by irradiating the ceramic plate material 101 with ultraviolet light having a wavelength of 300 nm or less; and step S16 of forming through-holes by irradiating the ceramic plate 100 with a laser beam, the ceramic plate 100 having the chroma C* changed by irradiating with ultraviolet light. The manufacturing method for the ceramic substrate according to Embodiment 2-1 preferably further includes step S11 of preparing a ceramic plate material, step S12 of applying a coating film, step S14 of removing the coating film, and step S15 of performing marking, and can further include other processes as necessary.

Step S14 of removing the coating film can be performed before step S16 of forming a through-hole, or can be performed after step S16 of forming through-holes. By performing step S14 of removing the coating film after step S16 of forming through-holes, residues of the ceramic plate 100 generated when forming through-holes 4 together with removing the coating film 10 can be removed, and residues and scratches adhering to the first surface 200a of the ceramic substrate 200 can be reduced.

In the manufacturing method for the ceramic substrate according to Embodiment 2-1, the ceramic plate 100 used for laser beam machining according to Embodiment 1-1 or Embodiment 1-2 of the present disclosure can be used as the ceramic plate material 101.

Step S11 of preparing the ceramic plate material to step S15 of performing marking in the manufacturing method for the ceramic substrate according to Embodiment 2-1 can be carried out in the same manner as step S1 of preparing the ceramic plate material to step S5 of performing marking in the pretreatment method according to the embodiment of the present disclosure; therefore, step S16 of forming through-holes will be described below.

### (S16) Forming Through-Holes

In step S16 of forming through-holes, the ceramic plate 100, which has been irradiated with ultraviolet light to change the chroma C*, is irradiated with a laser beam to form a through-hole 4. Specifically, the first surface 100a having the second portion 2 is irradiated with a laser beam. At this time, the laser beam is absorbed by the second portion 2, but not by the first portion 1. For this reason, the ceramic in the second portion 2 of the ceramic plate 100 is removed by melting and sublimation mainly in the second portion 2, thereby forming through-holes 4 in the second portion 2.

The through-hole 4 can be formed by irradiating with a laser beam once or can be formed by irradiating with a laser beam multiple times to gradually remove the ceramic plate 100, but it is preferable to irradiate the same place with a laser beam only once.

There is no particular limitation on the laser beam as long as it can form the through-hole 4; however, it is preferable that the laser beam include a wavelength of 355 nm or more (i.e. within the visible light or infrared range), more preferably 450 nm or more, and still more preferably 500 nm or more. Although the upper limit of the wavelength of the laser beam is also not particularly limited, it is preferable that the laser beam have visible light with a wavelength of 650 nm or less, more preferably 580 nm or less, and still more preferably 550 nm or less. These lower limit and upper limit of the wavelength of the laser beam can be suitably combined, and it is preferable that the laser beam have visible light with a wavelength of 355 nm or more and 650 nm or less, more preferably 450 nm or more and 580 nm or less, and still more preferably 500 nm or more and 550 nm or less. When the wavelength of the laser beam is visible light with a wavelength of 355 nm or more, the reflectance of the ceramic plate 100 decreases, and the through-hole 4 can be efficiently formed by laser beam machining.

Although the pulse width of the laser beam is not particularly limited, it is preferable that the laser beam include continuous wave (CW). The continuous wave is one in which the pulse width of the laser beam is maximized in a repetition period of a pulse.

Specific examples of the laser beam include green laser beam (having visible light with a wavelength of 532 nm).

Atmospheric conditions for irradiating the laser beam are not particularly limited and include, for example, a vacuum atmosphere and an inert gas atmosphere. Examples of inert gas include, for example, N₂ and CO₂. One of these can be used alone or two or more can be used in combination.

The pulse width and the output of the laser beam are not particularly limited.

The time from the time when the chroma C* is changed by irradiation with ultraviolet light to the start of irradiation with a laser beam is not particularly limited, but is preferably within fifteen minutes, more preferably within ten minutes, and still more preferably within five minutes. If the time from the time when the chroma C* is changed by irradiation with ultraviolet light to the start of irradiation with a laser beam is within fifteen minutes, the through-hole 4 can be efficiently formed by laser beam machining.

In step S16 of forming through-holes, the method can include positioning the ceramic plate 100 using the marks 3, irradiating the marks 3 with the laser beam before irradiating the second portion 2 with the laser beam, and performing a trial irradiation of a laser beam.

Conventionally, the blackening treatment of a ceramic plate requires a multi-step process of applying a blackening agent, such as carbon spray, to the surface of the ceramic plate material, drying the agent, performing laser beam machining on the ceramic plate, and then washing the ceramic plate to remove the carbon, which is very complicated.

On the other hand, in the ceramic substrate manufacturing method according to Embodiment 2-1, by step S13 of changing the chroma C*, the ceramic plate 100 is irradiated with ultraviolet light having a wavelength of 300 nm or less, thereby reducing the reflectance on the surface of the ceramic plate 100 and suppressing optical reflection. For this reason, the process of applying and drying the blackening agent is unnecessary, and laser beam machining can be performed efficiently. Since the chroma C* gradually returns to the state before the irradiation with ultraviolet light with the lapse of time after the irradiation with ultraviolet light, a cleaning step is unnecessary, and the chroma C* of the ceramic plate 100 returned to the state before the irradiation with ultraviolet light is suitable for a light-emitting device or the like.

### Embodiment 2-2

### Ceramic Substrate

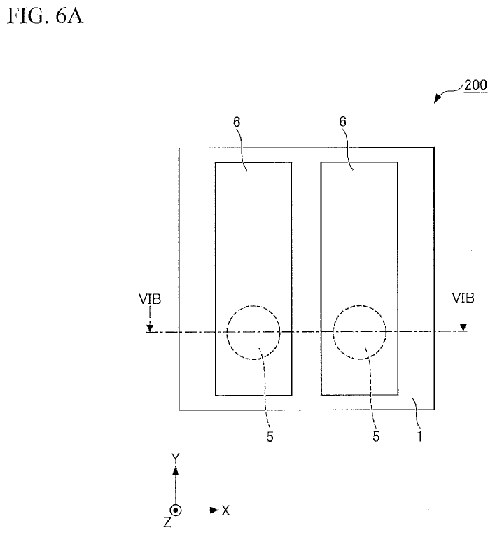

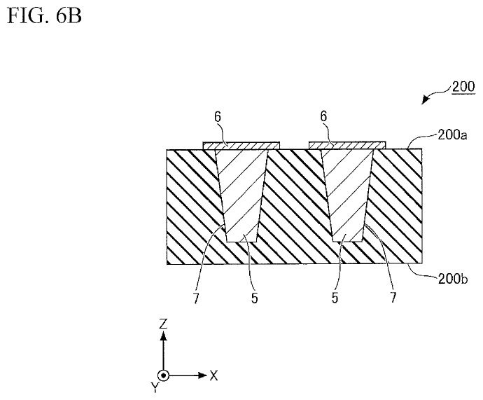

FIG. 6A is a schematic top view illustrating an example of a ceramic substrate according to Embodiment 2-2. FIG. 6B is a schematic cross-sectional view taken along line VIB-VIB in FIG. 6A. The ceramic substrate 200 according to Embodiment 2-2 includes the first surface 200a, the second surface 200b opposite to the first surface 200a, the first portion 1, and recesses 7. It is preferable that the ceramic substrate 200 further include the marks 3, the first conductive members 5, and the second conductive members 6.

The ceramic substrate 200 according to Embodiment 2-2 is the same as the ceramic substrate 200 according to Embodiment 2-1, except that ceramic substrate 200 according to Embodiment 2-2 has the recesses 7 instead of the through-holes 4, is provided with the first conductive members 5 inside the recesses 7, and is provided with the second conductive members 6 arranged only on the first surface 200a.

### Manufacturing Method for Ceramic Substrate

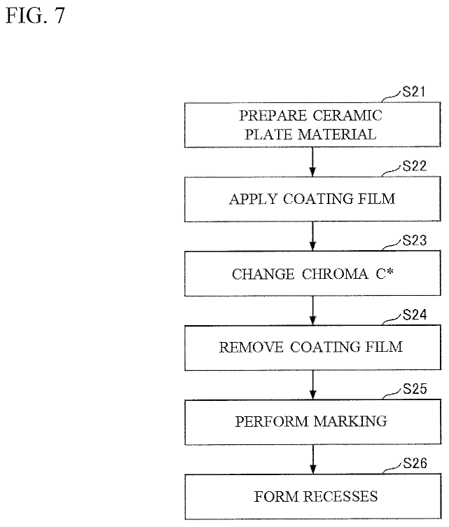

FIG. 7 is a flowchart illustrating an example of a manufacturing method for a ceramic substrate according to Embodiment 2-2. The manufacturing method for a ceramic substrate according to Embodiment 2-2 includes: step S23 of changing the chroma C* by irradiating the ceramic plate material 101 with ultraviolet light having a wavelength of 300 nm or less; and step S26 of forming recesses by irradiating the ceramic plate 100 with a laser beam, the ceramic plate 100 having the chroma C* that has been changed by irradiating ultraviolet light. The manufacturing method for a ceramic substrate according to Embodiment 2-2 preferably further includes step S21 of preparing a ceramic plate material, step S22 of applying a coating film, step S24 of removing the coating film, step S25 of performing marking, and further can include other processes as necessary.

The manufacturing method for a ceramic substrate according to Embodiment 2-2 includes step S26 of forming recesses instead of step S16 of forming through-holes. In other words, the method is the same as the manufacturing method for a ceramic substrate according to Embodiment 2-1 except that in step S26 of forming recesses, the laser beam irradiation condition is changed to a condition under which the recess 7 can be formed in the ceramic plate 100.

### Light-Emitting Device

### Embodiment 3-1

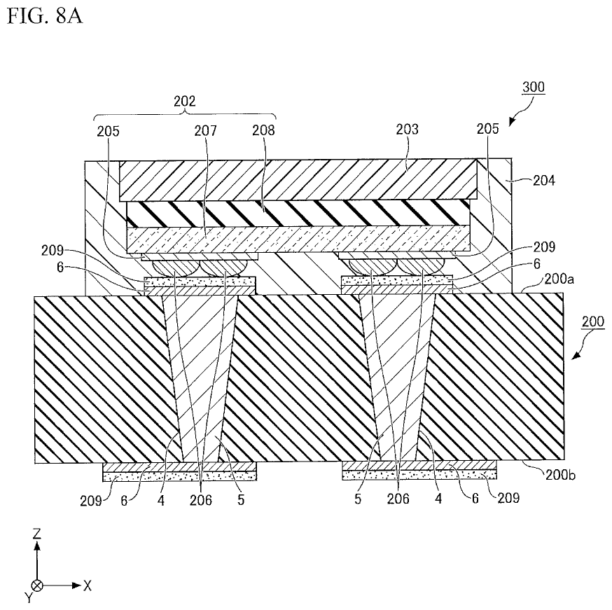

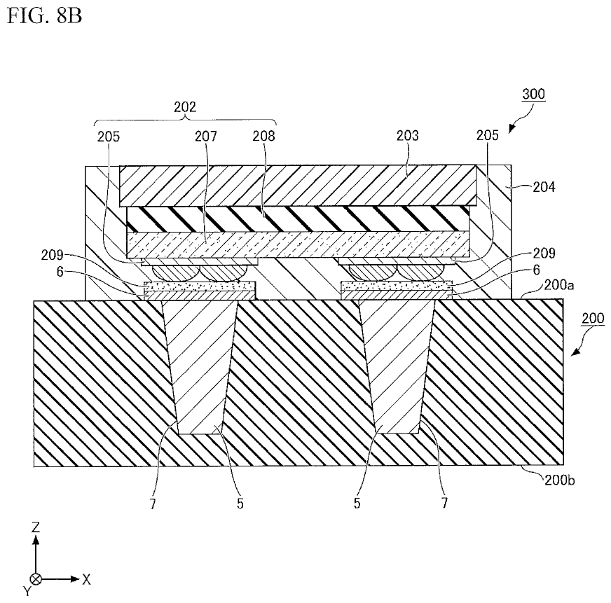

FIG. 8A is a schematic cross-sectional view illustrating an example of a light-emitting device according to Embodiment 3-1. Hereinafter, the respective configurations of a light-emitting device 300 will be described.

A light-emitting device 300 according to Embodiment 3-1 includes: the ceramic plate 100 having the first portion 1 and the marks 3 on the same surface; the ceramic substrate 200 having the through-holes 4, the first conductive members 5, and the second conductive members 6; and light-emitting elements 202 arranged on the ceramic substrate 200 and each having electrodes 205.

The ceramic substrate 200 is the ceramic substrate 200 according to Embodiment 2-1.

The light-emitting device 300 is a device in which light-emitting elements 202 are arranged on the ceramic substrate 200 to emit light. The number of the light-emitting elements 202 can be one or a plurality. When a plurality of light-emitting elements 202 are provided, there is no particular limitation on the arrangement of the light-emitting elements 202, and for example, they can be arranged in a line.

The light-emitting device 300 includes, for example, translucent members 203 covering the light extraction surfaces of the light-emitting elements 202, a light reflecting member 204 covering the side surfaces of the light-emitting elements 202 and the first surface 200a of the ceramic substrate 200, and metal bumps 206 electrically connecting the light-emitting elements 202 to the first conductive members 5 and the second conductive members 6 of the ceramic substrate 200.

In the ceramic substrate 200, various patterns of interconnect can be formed depending on the application, but in the light-emitting device 300 according to the embodiment, each light-emitting element 202 has a pair of electrodes 205 on the same surface, and is face-down mounted, with the surface having the electrodes 205 facing the first surface 200a of the ceramic substrate 200.

The light-emitting device 300 according to the embodiment can be face-up mounted with the pair of electrodes 205 of the light-emitting element 202 mounted on the opposite side of the surface in contact with the ceramic substrate 200 and connected to the first conductive member 5 of the first surface 200a of the ceramic substrate 200 by wires.

### Light-Emitting Element 202

The light-emitting element 202 has the pair of electrodes 205, a semiconductor stack body 207, and an element substrate 208.

As an example, the light-emitting element 202 has the semiconductor stack body 207 on the bottom side of the element substrate 208 and the pair of electrodes 205 on the side of the semiconductor stack body 207.

As the semiconductor stack body 207, any composition can be used in accordance with a desired emission wavelength, for example, nitride semiconductor (InₓAl_{y}Ga_{1-x-y}N, 0<X, 0<Y, X+Y<1) or GaP capable of emitting blue or green light, or GaAlAs or AlInGaP capable of emitting red light can be used. One of these can be used alone, or two or more can be used in combination. The size and shape of the light-emitting element 202 can be appropriately selected in accordance with the purpose of use.

As an example, a sapphire substrate or a silicon substrate is used as the element substrate 208.

The electrode 205 is electrically connected to the first conductive member 5 of the ceramic substrate 200 by a metal bump 206 via a bonding member 209. The pair of electrodes 205 includes a p-type electrode and an n-type electrode, which are arranged so as to be electrically insulated from each other and thereby prevented from short-circuiting. In one example, the p-type electrode and the n-type electrode are each provided at a single respective location among the electrodes 205. Alternatively, one of the p-type electrode and the n-type electrode can be provided at two locations, while the other is provided at a single location.

### Translucent Member 203

The translucent member 203 is arranged on a plane side of the element substrate 208 serving as a light extraction surface. The translucent member 203 is made of a translucent resin material. By way of example, an epoxy resin, a silicone resin, or a resin composition comprising a mixture of an epoxy resin and a silicone resin can be used as the translucent resin material. The translucent member 203 can include a phosphor, and can emit white light by including, for example, a phosphor that absorbs blue light from the light-emitting element 202 and emits yellow light. The translucent member 203 can also include a plurality of types of phosphors, and can emit white light from the light-emitting element 202 by including, for example, a phosphor that absorbs blue light from the semiconductor stack body 207 and emits green light and a phosphor that emits red light.

A phosphor that can be excited by light emission from the light-emitting element 202 is used as the phosphor included in the translucent member 203. For example, one of the following specific examples can be used alone, or a combination of two or more of them can be used. Specific examples of phosphors that can be excited by a blue light-emitting device or an ultraviolet light-emitting device include:
yttrium-aluminum-garnet-based phosphors activated with cerium (for example, Y₃(Al, Ga)₅O₁₂:Ce);
lutetium-aluminum-garnet-based phosphors activated with cerium (for example, Lu₃(Al, Ga)₅O₁₂:Ce);
nitrogen-containing calcium aluminosilicate-based phosphors activated with europium and/or chromium (for example, CaO—Al₂O₃—SiO₂:Eu);
terbium-aluminum-garnet-based phosphors (for example, Tb₃(Al, Ga)₅O₁₂:Ce);
silicate-based phosphors activated with europium (for example, (Sr, Ba)₂SiO₄:Eu);
nitride-based phosphors, such as β-sialon-based phosphors (for example, Si_{6-z}Al_{z}O_{z}N_{8-z}:Eu (0<Z<4.2)), α-sialon-based phosphors (for example, M_{z}(Si, Al)₁₂(O, N)₁₆ (where 0<z≤2, and M is Li, Mg, Ca, Y, and lanthanide elements except La and Ce), CASN-based phosphors (for example, CaAlSiN₃:Eu), and SCASN-based phosphors (for example, (Sr, Ca)AlSiN₃:Eu);
potassium fluorosilicate-based phosphors activated with manganese (for example, K₂SiF₆:Mn, K₂(Si, Al)F₆:Mn, _{3.5}MgO·_{0.5}MgF₂·GeO₂:Mn);
sulfide-based phosphors; and
quantum dot phosphors (for example, perovskite, chalcopyrite).

By combining these phosphors with a blue light-emitting element or an ultraviolet light-emitting element, light-emitting devices (for example, a white light-emitting device) of various colors can be manufactured. In the case of a light-emitting device capable of emitting light in white, the light-emitting device is adjusted to be white depending on the type and concentration of phosphor contained in the translucent member 203. When such phosphor is contained in the translucent member 203, the concentration of phosphor is preferably about 5% to 50%.

### Metal Bump 206

The metal bump 206 is a member for electrically connecting the electrode 205 to the first conductive member 5 and the second conductive member 6. The metal bump 206 can be arranged on either the electrode 205 side or the second conductive member 6 side. The shape, size, and number of the metal bumps 206 can be appropriately set as long as they can be arranged within the range of the electrode 205. The size of the metal bump 206 can be appropriately adjusted depending on the size of the semiconductor stack body 207, the required light emission output of the light-emitting element, and the like, and for example, the size can range from several tens of micrometers to several hundreds of micrometers in diameter.

The metal bump 206 can be formed of, for example, Au, Ag, Cu, Al, Sn, Pt, Zn, Ni, or an alloy of these metals. The metal bump 206 can be formed, for example, by a stud bump known in the art. The stud bump can be formed by a stud bump bonder, a wire bonding apparatus, or the like. The metal bump 206 can be formed by a method known in the art, such as electrolytic plating, electroless plating, vapor deposition, sputtering, or the like.

As an example, the metal bump 206 is bonded via a bonding member 209. Examples of the bonding member 209 used herein include: solders, such as tin-bismuth, tin-copper, tin-silver, and gold-tin; eutectic alloys such as alloys containing Au and Sn as main components; alloys containing Au and Si as main components; alloys containing Au and Ge as main components; paste materials such as silver, gold, and palladium; anisotropic conductive materials such as ACP and ACF; brazing materials of low-melting-point metals; conductive adhesive materials obtained by combining these materials, and conductive composite adhesive materials.

### Light Reflecting Member 204

The light reflecting member 204 is a member having light reflectivity. The light reflecting member 204 is arranged so as to cover the first surface 200a of the ceramic substrate 200 and the side surface of the light-emitting elements 202. The light reflecting member 204 is arranged so as to expose the light extraction surfaces of the light-emitting elements 202, and is arranged so as to be flush with the light reflecting member 204 of the light-emitting elements 202. As an example, the light reflecting member 204 is also arranged between the lower surfaces of the light-emitting elements 202 and the first surface 200a of the ceramic substrate 200.

To efficiently utilize light emitted from the light-emitting elements 202, the light reflecting member 204 preferably exhibits high reflectance. The light-reflecting member 204 is preferably white. The reflectance of the light reflecting member 204 at the wavelength of light emitted from the light-emitting elements 202 is preferably 90% or more, and more preferably 94% or more.

As the resin for the light reflecting member 204, for example, a thermoplastic resin, such as an acrylic resin, a polycarbonate resin, a cyclic polyolefin resin, a polyethylene terephthalate resin, a polyethylene naphthalate resin and a polyester resin, or a thermosetting resin, such as an epoxy resin and a silicone resin, can be used. As the light diffusing material, for example, a known material such as titanium oxide, silicon oxide, aluminum oxide, zinc oxide or glass can be used.

In the light-emitting device 300, a single light-emitting element 202 is used as a control unit for brightness and point off as one unit, but the number of light-emitting elements 202 included in one unit can be one or a plurality. For example, four light-emitting elements 202 of one row and four columns or two rows and two columns or nine light-emitting elements 202 of three rows and three columns can be used as one unit, and the number of light-emitting elements 202 is not limited.

### Embodiment 3-2

FIG. 8B is a schematic cross-sectional view illustrating an example of a light-emitting device according to Embodiment 3-2. The light-emitting device 300 according to Embodiment 3-2 includes: the ceramic plate 100 having the first portion 1 and the marks 3 on the same surface; the ceramic substrate 200 having the recesses 7, the first conductive members 5, and the second conductive members 6; and the light-emitting elements 202 arranged on the ceramic substrate 200 and each having the electrodes 205.

The ceramic substrate 200 is the ceramic substrate 200 according to Embodiment 2-2. The light-emitting device according to Embodiment 3-2 is the same as the light-emitting device according to Embodiment 3-1 except that the recesses 7 is provided instead of the through-holes 4.

The ceramic substrate 200 can be exposed from the bottom surface of the recesses 7 by polishing or grinding the second surface 200b, thereby exposing the first conductive members 5 from the second surface 200b. As a result, the first surface 200a and the second surface 200b can be electrically connected.

### Application Example of Light-Emitting Device

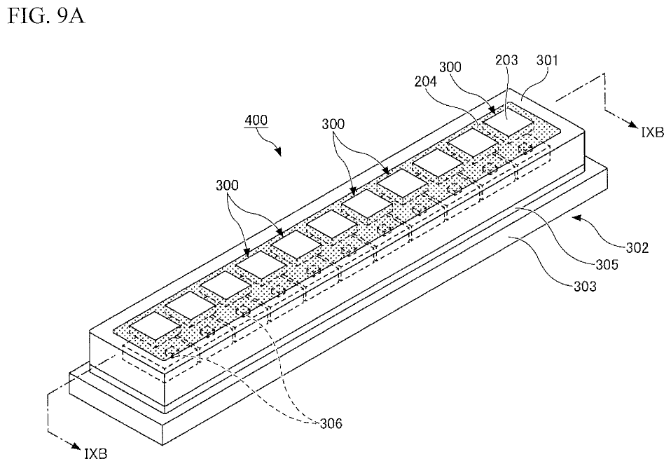

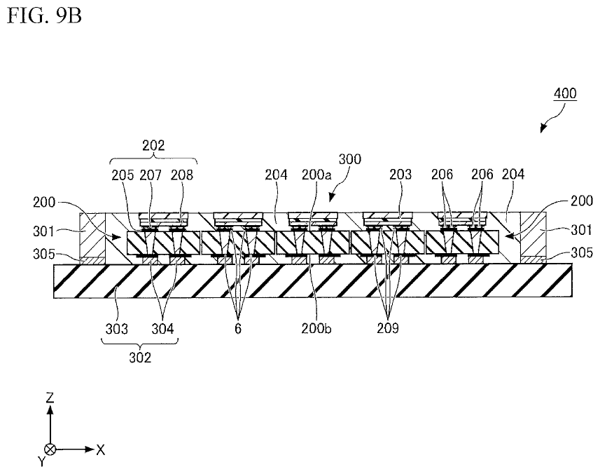

FIG. 9A is a perspective view illustrating an application example of the light-emitting device according to Embodiment 3-1. FIG. 9B is a sectional view taken along line IXB-IXB in FIG. 9A. FIG. 9B illustrates the structure with a part of the configuration illustrated in FIG. 9A omitted.

The light-emitting device 300 can be provided as a light-emitting module 400 including a plurality of light-emitting devices arranged in a single row (eleven devices in FIG. 9A), and the eleven light-emitting devices 300 can be mounted on a single ceramic substrate 200. A configuration of the light-emitting module 400 will now be described.

The light-emitting module 400 is provided with eleven light-emitting devices 300 in a row, has a light reflecting member 204 on the outer periphery of the light-emitting devices 300, has a frame 301 on the outside of the light reflecting member 204, and has a module substrate 302 connected to the surface of the ceramic substrate 200 opposite to the first surface 200a.

The frame 301 is a member for surrounding the light reflecting member 204 covering the plurality of light-emitting devices 300. The frame 301 is formed into a rectangular annular shape which is, for example, rectangular in a plan view, and is arranged so as to surround the periphery of the light reflecting member 204.

The frame 301 can be formed by using a frame-like member made of a metal, an alloy, or ceramics. Examples of the metal include Fe, Cu, Ni, Al, Ag, Au, Pt, Ti, W, and Pd. Examples of the alloy include an alloy containing at least one metal selected from the group consisting of Fe, Cu, Ni, Al, Ag, Au, Pt, Ti, W, and Pd.

Alternatively, a resin material can be used as the frame 301. In this case, the metal, alloy, or ceramic member can be embedded in the frame 301 formed of a resin material, or a part of the frame 301 can be formed of a resin material and the other part can be formed of a metal, alloy, or ceramic member.

The module substrate 302 is a member on which the light-emitting devices 300 are mounted, and electrically connects the light-emitting devices 300 to the outside. The module substrate 302 is formed, for example, into a substantially rectangular shape in a plan view. The module substrate 302 includes a substrate portion 303 and an interconnect board portion 304.

As the material of the substrate portion 303, it is preferable to use, for example, an insulating material that is substantially impermeable to light emitted from the light-emitting elements 202, as well as to external light. For example, ceramics, such as aluminum oxide, aluminum nitride, mullite, and the like, thermoplastic resins, such as polyamide, polyphthalamide, polyphenylene sulfide, liquid crystal polymers, and the like, resins such as epoxy resins, silicone resins, modified epoxy resins, urethane resins, and phenolic resins, can be used. Among these, it is preferable to use ceramics excellent in heat dissipation characteristics as the material of the substrate portion 303.

The interconnect board portions 304 are formed on the substrate portion 303 at positions facing the second conductive members 6 on the second surface 200b of the ceramic substrate 200 of the light-emitting device 300. Examples of the materials of the interconnect board portions 304 include those exemplified as materials used for the first conductive members 5 and the second conductive members 6.

The module substrate 302 is arranged in such a manner that the module substrate 302 is bonded to the frame 301 through a conductive adhesive 305 and the second conductive members 6 are bonded to the interconnect board portions 304. The conductive adhesive 305 can be, for example, eutectic solder, conductive paste, bumps, or the like. In the light-emitting devices 300, protective elements 306 are arranged on the ceramic substrate 200 in parallel with the light-emitting elements 202.

Since the light-emitting module 400 is configured as described above, when driven, the following occurs. In the light-emitting module 400, a current is supplied to the light-emitting elements 202 from an external power source through the interconnect board portions 304, the first conductive members 5, the second conductive members 6, and the electrodes 205, thereby causing the light-emitting elements 202 to emit light. As for the light emitted by the light-emitting elements 202, the light traveling upward is taken out to the outside above the light-emitting devices 300 through the translucent members 203. Light traveling downward is reflected by the ceramic substrate 200 and taken out to the outside of the light-emitting devices 300 through the translucent members 203. Light traveling between the light-emitting elements 202 and the frame 301 is reflected by the light reflecting member 204 and the frame 301 and taken out to the outside of the light-emitting devices 300 through the translucent members 203. Light traveling between the light-emitting elements 202 is reflected by the light reflecting member 204 and taken out to the outside of the light-emitting devices 300 through the translucent members 203. At this time, by narrowing the distance between the translucent members 203 (for example, 0.2 mm or less), for example, when the light-emitting module 400 is used as a light source of a headlight for a vehicle, the configuration of the optical system can be simplified and reduced in size.

In manufacturing the light-emitting module 400, the light-emitting devices 300 are arranged on a sheet member, the frame 301 is arranged around the light-emitting devices 300, and the space surrounded by the frame 301 and the sheet member is filled with the light reflecting member 204 in this state, thereby arranging the light reflecting member 204. Thereafter, the light-emitting devices 300 supported by the frame 301 and the light reflecting member 204 are arranged on the module substrate 302 on which the interconnect board portions 304 and the conductive adhesive 305 are arranged, and the light-emitting module 400 is manufactured by electrically connecting the first conductive members 5, the second conductive members 6, and the interconnect board portions 304.

### Manufacturing Method for Light-Emitting Device

A manufacturing method for a light-emitting device according to an embodiment includes: preparing the ceramic substrate 200 manufactured by the manufacturing method for a ceramic substrate according to Embodiment 2-1 or Embodiment 2-2; and arranging light-emitting elements 202, each having electrodes 205, on the ceramic substrate 200.

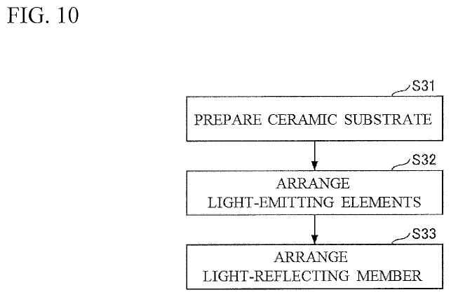

FIG. 10 is a flowchart illustrating an example of the manufacturing method for a light-emitting device according to the embodiment. The manufacturing method for the light-emitting device according to the embodiment includes, as an example, arranging a light reflecting member.

### (S31) Preparing a Ceramic Substrate

In step S31 of preparing the ceramic substrate 200, the ceramic substrate 200 of the present disclosure is prepared.

The ceramic substrate 200 can have a plurality of regions in which the light-emitting elements 202 are arranged, and can be sized so as to be singulated for each light-emitting device 300 after the light reflecting member 204 is arranged, or can be sized for each light-emitting device 300.

### (S32) Arranging Light-Emitting Elements

In step S32 of arranging light-emitting elements, the light-emitting elements 202 each having the electrode 205 are arranged on the ceramic substrate 200. In step S32 of arranging light-emitting elements, the electrodes 205 of the light-emitting element 202 are connected to the bonding members 209 arranged on the second conductive members 6 by the metal bumps 206. The light-emitting elements 202 are arranged in such a state that the translucent members 203 are connected to the element substrate 208 in advance. When the translucent members 203 are bonded to the element substrate 208, a light-transmitting bonding material is used.

### (S33) Arranging a Light Reflecting Member

In step S33 of arranging a light reflecting member, the light reflecting member 204 is arranged so as to cover the first surface 200a of the ceramic substrate 200 and to cover the side surfaces of the light-emitting elements 202. The light-reflecting member 204 is arranged on the ceramic substrate 200 such that it surrounds the light-emitting elements 202 and exposes the upper surfaces of the translucent members 203 that serve as the light extraction surfaces of the light-emitting elements 202. The light reflecting member 204 is arranged so as to be rectangular in a plan view.

In the manufacturing method for a light-emitting device according to the embodiment, after step S33 of arranging light reflecting members, singulation is performed as necessary. In the light-emitting device 300, one unit of the light-emitting device 300 is predetermined by the number of the light-emitting elements 202 used. Accordingly, when a plurality of the light-emitting devices 300 are manufactured in a batch, singulation is performed. During the singulation process, a substrate on which a plurality of the light-emitting devices 300 are arranged is cut in a grid pattern. Examples of a cutting method include a method using a disc-shaped rotary blade, an ultrasonic cutter, a laser beam irradiation blade, and the like.

### EXAMPLES

The present invention will be described in detail with reference to test examples, but the present invention is not limited to these test examples.

### Test Example 1: Examination of Irradiance of Ultraviolet Light

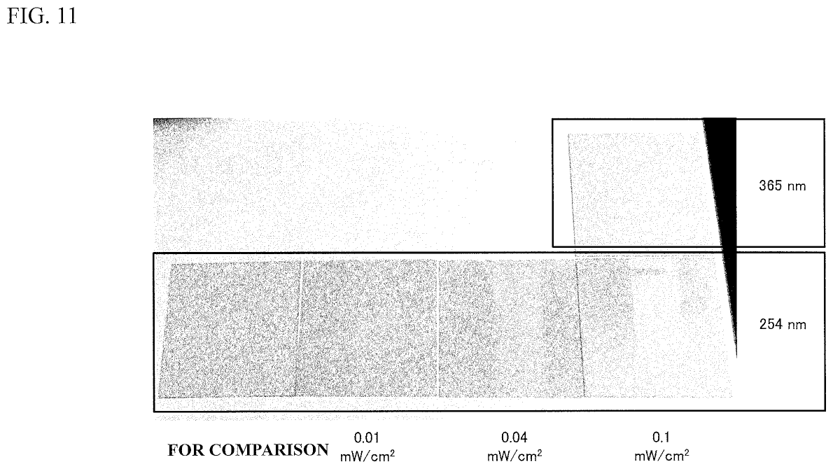

Under illumination of a general fluorescent lamp, a light-shielding plate (SUS plate) was placed so as to cover a part of the ceramic plate material 101 made mainly of silicon nitride, and ultraviolet light having a wavelength of 254 nm or 365 nm was radiated for two minutes from above the light-shielding plate using a UV-lamp (SLUV-8, manufactured by AS ONE Corporation). During the radiation of ultraviolet light having a wavelength of 254 nm, the irradiance was changed to 0.1 mW/cm², 0.4 mW/cm², and 1.0 mW/cm², and the color development of the ceramic plate material 101 was confirmed visually. The irradiation with ultraviolet light having a wavelength of 365 nm was carried out at an irradiance of 1.0 mW/cm². The results are illustrated in FIG. 11. A control which was not irradiated with ultraviolet light was also illustrated for comparison.

As illustrated in FIG. 11, almost no color was observed in the irradiation with ultraviolet light having a wavelength of 365 nm. On the other hand, in the irradiation with ultraviolet light having a wavelength of 254 nm, color was observed at an irradiance of 0.1 mW/cm² or more.

### Test Example 2: Measurement of Lightness L*, Chromaticity Values a* and b*, and Chroma C* Before and After Irradiation with Ultraviolet Light

Under illumination of a general fluorescent lamp, a ceramic plate material 101 made of aluminum nitride as a main material, the ceramic plate material 101 made of silicon nitride as a main material, the ceramic plate material 101 made of aluminum oxide as a main material, and the ceramic plate material 101 made of boron nitride as a main material were irradiated with ultraviolet light having a wavelength of 254 nm using a UV-lamp (SLUV-8, manufactured by AS ONE Corporation) at the irradiance and irradiation time illustrated in Table 1. The lightness L*, chromaticity values a* and b*, and chroma C* of the ceramic plate material 101 before irradiation, the ceramic plate 100 immediately after irradiation (within one minute from the end of irradiation), and the ceramic plate 100 100 hours after the end of irradiation were measured with a spectral densitometer (FD-5, manufactured by Konica Minolta Japan Co., Ltd.). The results are illustrated in Table 1.

TABLE 1

| | Ultraviolet light irradiation conditions | | | | | | | |
|---|---|---|---|---|---|---|---|---|
| | | | Illumination | | | | | |
| Ceramic Plate | Wavelength | Illuminance | time | Elapsed time at | Lightness | Chromaticity | | Chroma |
| Material 101 | (nm) | (mW/cm²) | (minutes) | measurement | L* | a* | b* | C* |
| Aluminum | 254 | 0.10 | 5 | Before irradiation | 59.67 | 0.29 | 5.80 | 5.80 |
| nitride | 254 | 0.10 | 5 | Immediately after | 50.41 | 8.95 | 26.44 | 27.92 |
| | | | | irradiation | | | | |
| | 254 | 0.10 | 1 | 100 hours after | 58.31 | 0.58 | 8.74 | 8.76 |
| | | | | irradiation | | | | |
| Silicon | 254 | 0.10 | 2 | Before irradiation | 79.20 | 1.70 | 12.77 | 12.88 |
| nitride | 254 | 0.10 | 2 | Immediately after | 71.69 | 6.43 | 20.93 | 21.90 |
| | | | | irradiation | | | | |
| | 254 | 0.10 | 2 | 72 hours after | 74.12 | 6.16 | 21.52 | 22.38 |
| | | | | irradiation | | | | |
| Aluminum | 254 | 0.10 | 2 | Before irradiation | 97.68 | −0.09 | 0.30 | 0.31 |
| oxide | 254 | 0.10 | 2 | Immediately after | 97.42 | −0.09 | 3.39 | 3.39 |
| | | | | irradiation | | | | |
| | 254 | 0.10 | 2 | 72 hours after | 97.21 | −0.18 | 3.11 | 3.12 |
| | | | | irradiation | | | | |
| Boron | 254 | 0.10 | 2 | Before irradiation | 94.66 | −0.36 | 3.29 | 3.31 |
| nitride | 254 | 0.10 | 2 | Immediately after | 93.45 | 0.21 | 5.19 | 5.19 |
| | | | | irradiation | | | | |
| | 254 | 0.10 | 2 | 72 hours after | 93.80 | 0.03 | 5.07 | 5.07 |
| | | | | irradiation | | | | |

### Test Example 3: Measurement of Reflectance Before and After Irradiation with Ultraviolet Light

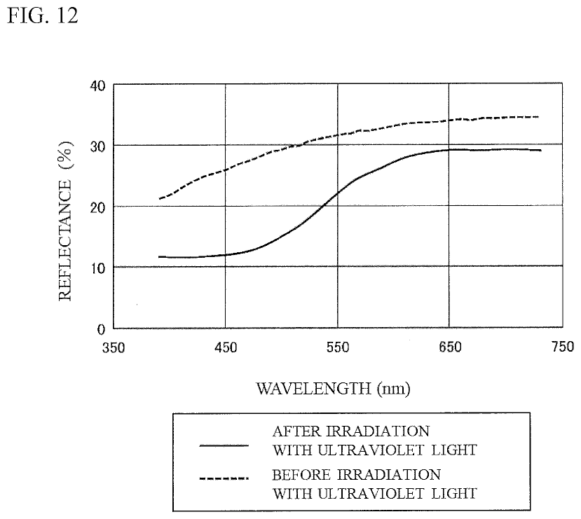

The ceramic plate material 101 mainly made of aluminum nitride was irradiated with ultraviolet light having a wavelength of 254 nm using a UV-lamp (SLUV-8, manufactured by AS ONE Corporation) at an irradiance of 1.0 mW/cm² for five minutes to form the ceramic plate 100. When measuring the reflectance of the ceramic plate 100, a black plate was placed on the surface opposite to the surface irradiated with ultraviolet light in order to prevent transmission of light through the ceramic plate 100, and the reflectance of the ultraviolet-light-irradiated surface was measured in a wavelength range from 390 nm to 730 nm using a spectrocolorimeter (CMS-35SP, manufactured by Murakami Color Research Institute, Inc.). For comparison, a black plate was also placed on one surface of the ceramic plate material 101 that has not been irradiated with ultraviolet light, and the reflectance of the other surface in a wavelength range from 390 nm to 730 nm was measured with a spectrocolorimeter. The results are illustrated in FIG. 12.

From the results of FIG. 12, it was found that the reflectance of the surface irradiated with ultraviolet light decreased in the whole wavelength range measured, and the decrease in reflectance was particularly large at 600 nm or less. Therefore, it was suggested that the surface irradiated with ultraviolet light was suitable for processing a green laser having a wavelength of 532 nm or the like.

As described above, the present invention has been described on the basis of specific embodiments, but these are provided only as examples, and the present invention is not limited by the above-described embodiments. The above-described embodiments can be carried out in various other forms, and various combinations, omissions, substitutions, additions, modifications, and the like can be made without departing from the gist of the invention. These embodiments and variations of the embodiments are included in the scope and gist of the invention, and are included equally with the claimed invention.

1. A pretreatment method for a ceramic plate used for laser beam machining, the method comprising:
changing a chroma C* of a ceramic plate material by irradiating the ceramic plate material with ultraviolet light having a wavelength of 300 nm or less.

2. The pretreatment method according to claim 1, wherein
the ceramic plate material contains at least one material selected from a group consisting of aluminum nitride, silicon nitride, aluminum oxide, and boron nitride.

3. The pretreatment method according to claim 1, wherein
in changing the chroma C* by irradiating the ceramic plate material with ultraviolet light of a wavelength of 300 nm or less, an irradiation time is 7 minutes or less.

4. The pretreatment method according to claim 1, wherein
in changing the chroma C* by irradiating the ceramic plate material with ultraviolet light of a wavelength of 300 nm or less, the irradiance of ultraviolet light is 0.1 mW/cm² or more.

5. A manufacturing method for a ceramic substrate, the method comprising:
changing a chroma C* of a ceramic plate material by irradiating the ceramic plate material with ultraviolet light having a wavelength of 300 nm or less; and
irradiating the ceramic plate, whose chroma C* has been changed by the ultraviolet irradiation, with a laser beam to form a recess or a through-hole.

6. The manufacturing method for the ceramic substrate according to claim 5, wherein
the ceramic plate material contains at least one material selected from a group consisting of aluminum nitride, silicon nitride, aluminum oxide, and boron nitride.

7. The manufacturing method for the ceramic substrate according to claim 5, wherein
in changing the chroma C* by irradiating the ceramic plate material with ultraviolet light of a wavelength of 300 nm or less, the irradiation time is 7 minutes or less.

8. The manufacturing method for the ceramic substrate according to claim 5, wherein
in changing the chroma C* by irradiating the ceramic plate material with ultraviolet light of the wavelength of 300 nm or less, the irradiance is 0.1 mW/cm² or more.

9. The manufacturing method for the ceramic substrate according to claim 5, wherein
in forming the recess or the through-hole, the laser beam has a wavelength of 355 nm or more.

10. The manufacturing method for the ceramic substrate according to claim 5, wherein
a period of time from changing the chroma C* by ultraviolet irradiation to the start of the laser irradiation is 15 minutes or less.

11. The manufacturing method for the ceramic substrate according to claim 5, wherein
the ceramic plate material is aluminum nitride,
in changing the chroma C* by irradiating the ceramic plate material with ultraviolet light of the wavelength of 300 nm or less, the ceramic plate material before irradiation has a b* value in a L*a*b* color system of less than 7.5 and a chroma C* of less than 7.5,
the ceramic plate immediately after irradiation has a b* value in a L*a*b* color system of 15.0 or greater and a chroma C* of 15.0 or greater, and
the ceramic plate 100 hours after the end of irradiation has a b* value in the L*a*b* color system of 7.5 or greater and a chroma C* of 7.5 or greater.

12. The manufacturing method for the ceramic substrate according to claim 5, wherein
the ceramic plate material is silicon nitride,
in changing the chroma C* by irradiating the ceramic plate material with ultraviolet light of a wavelength of 300 nm or less, the ceramic plate material before irradiation has a b* value in a L*a*b* color system of less than 16.0 and a chroma C* of less than 16.0, and
the ceramic plate immediately after the irradiation has a b* value in the L*a*b* color system of 16.0 or greater and a chroma C* of 16.0 or greater.

13. The manufacturing method for the ceramic substrate according to claim 5, the method further comprising:
applying a coating film having a desired shape to the ceramic plate material prior to changing the chroma C* by ultraviolet irradiation.

14. A manufacturing method for a light-emitting device, the method comprising:
preparing the ceramic substrate manufactured by the manufacturing method for the ceramic substrate according to claim 5; and
arranging a light-emitting element having an electrode on the ceramic substrate.

15. A ceramic plate used for laser beam machining, the ceramic plate comprising aluminum nitride and including, on a same surface, a first portion and a second portion, wherein the first portion has a b* value in a L*a*b* color system of 3.0 or greater and less than 7.5 and a chroma C* of 3.0 or greater and less than 7.5, and the second portion has a b* value in the L*a*b* color system of 7.5 or greater and 12.0 or less and a chroma C* of 7.5 or greater and 12.0 or less.

16. A ceramic plate used for laser beam machining, the ceramic plate comprising silicon nitride and including, on a same surface, a first portion and a second portion, wherein the first portion has a b* value in a L*a*b* color system of 3.0 or greater and less than 16.0 and a chroma C* of 3.0 or greater and less than 16.0, and the second portion has a b* value in the L*a*b* color system of 16.0 or greater and 23.0 or less and a chroma C* of 16.0 or greater and 25.0 or less.

17. A light-emitting device comprising:
a ceramic plate containing aluminum nitride and including
on a same surface, a first portion and a second portion, the first portion having a b* value in a L*a*b* color system of 3.0 or greater and less than 7.5 and a chroma C* of 3.0 or greater and less than 7.5, and the second portion having a b* value in the L*a*b* color system of 7.5 or greater and 12.0 or less and a chroma C* of 7.5 or greater and 12.0 or less;
a recess or a through-hole arranged in at least one region of the second portion; and
a light-emitting element arranged on the ceramic substrate and having an electrode.

18. A light-emitting device comprising:
a ceramic plate containing silicon nitride and including
on a same surface, a first portion and a second portion, the first portion having a b* value in a L*a*b* color system of 3.0 or greater and less than 16.0 and a chroma C* of 3.0 or greater and less than 16.0, and the second portion having a b* value in the L*a*b* color system of 16.0 or greater and 23.0 or less and a chroma C* of 16.0 or greater and 25.0 or less; and
a recess or a through-hole arranged in at least one region of the second portion; and
a light-emitting element arranged on the ceramic substrate and having an electrode.
